(19) United States
(12) Patent Application Publication
(10) Pub. No.: US 2007/0069192 A1
(43) Pub. Date: Mar. 29, 2007

(54) Thermal switching element and method for manufacturing the same

(75) Inventors: Akihiro Odagawa, Tsuchiura-shi (JP); Yasunari Sugita, Osaka-shi (JP); Hideaki Adachi, Hirakata-shi (JP); Masahiro Deguchi, Hirakata-shi (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Osaka (JP)

(21) Appl. No.: 11/605,064

(22) Filed: Nov. 28, 2006

Related U.S. Application Data
(63) Continuation of application No. 10/865,130, filed on Jun. 10, 2004.
Application No. 10/865,130 is a continuation of application No. PCT/JP04/00845, filed on Jan. 29, 2004.

(30) Foreign Application Priority Data
Jan. 30, 2003 (JP) 2003-021841
Sep. 17, 2003 (JP) 2003-324404

(51) Int. Cl. H01L 29/02

(52) U.S. Cl. 257/2

(57) ABSTRACT

The present invention provides a thermal switching element that has a quite different configuration from that of a conventional technique and can control heat transfer by the application of energy, and a method for manufacturing the thermal switching element. The thermal switching element includes a first electrode, a second electrode, and a transition body arranged between the first electrode and the second electrode. The transition body includes a material that causes an electronic phase transition by application of energy. The thermal conductivity between the first electrode and the second electrode is changed by the application of energy to the transition body.

This application is a continuation of U.S. Ser. No. 10/865,130 filed Jun. 10, 2004, which is a continuation of International application PCT/JP2004/000845, filed Jan. 29, 2004, which applications are incorporated herewith by reference.

### BACKGROUND OF THE INVENTION

1. Field of the Invention

The present invention relates to a thermal switching element that can control heat transfer and a method for manufacturing the thermal switching element.

2. Description of the Related Art

If there is a thermal switching element that can control heat transfer, the element is applicable in various fields. For example, the thermal switching element may be applied to the field of cooling technology for transferring heat in a specified direction. In this case, the element also can be called a cooling element.

Conventional cooling technologies can be classified into two major categories: a technology using the compression-expansion cycle of a coolant; and a technology using a thermoelectric phenomenon. For the technology using the compression-expansion cycle of a coolant, the coolant is compressed mainly with a compressor. This technology has the advantage of excellent efficiency resulting, e.g., from long years of technical improvements in compressors, and thus is applied widely to consumer appliances such as a freezer, refrigerator, and air conditioner. However, most of the coolant includes chlorofluorocarbon, and the environmental characteristics of chlorofluorocarbon have been a problem. Although an alternative to chlorofluorocarbon is being studied as the coolant at present, so far no coolant material has been developed that can exhibit heat transfer characteristics comparable to those of chlorofluorocarbon by the compression-expansion cycle.

On the other hand, an element (thermoelectric element) using a thermoelectric phenomenon provides cooling without any coolant. Therefore, this element not only can have excellent environmental characteristics, but also can be essentially maintenance free because a mechanical structure is not necessary. A typical example of the thermoelectric element is a Peltier element. However, the thermoelectric element is not applied to a refrigerator or air conditioner, although there are some exceptions, since the efficiency is low with the current technology. For example, when a coolant is used, the Carnot efficiency at operating temperatures (e.g., −25° C. to 25° C.) of a refrigerator or the like may be in the range of about 30% to 50%. However, the efficiency of the Peltier element is less than 10%. Moreover, a potential thermoelectric element other than the Peltier element has not been developed yet.

Thus, there is a growing demand for a thermal switching element that can transfer heat without any coolant such as chlorofluorocarbon and is distinguished from a conventional thermoelectric element.

When the thermal switching element is combined, e.g., with a heat conductor, a heat insulator, or a heating element, it is also possible to provide a thermal solid-state circuit element having a structure and function similar to those of an electric circuit element. To control heat transfer, active control of electrons that transfer heat is required. In a conventional thermoelectric element, however, it is difficult to control the electrons actively. For example, a thermoelectric phenomenon is attributed to heat transfer caused by electrons that are transported while drifting in a material. The characteristics (thermoelectric characteristics) of the thermoelectric element generally are. represented by a thermoelectric index ZT. The larger ZT is, the higher the efficiency of the element becomes. The thermoelectric index ZT is expressed by a formula S²T/κρ (where S is thermoelectric power, T is an absolute temperature, κ is a thermal conductivity, and ρ is a specific electric resistance). This formula indicates that the transport characteristics of electrons in the element significantly contribute to the thermoelectric characteristics. Accordingly, the electron density or the like may affect the thermoelectric characteristics of the element. However, it is difficult to actively control the electron transport characteristics of a conventional thermoelectric element, such as a Peltier element.

### SUMMARY OF THE INVENTION

Therefore, with the foregoing in mind, it is an object of the present invention to provide a thermal switching element that can control heat transfer by having a quite different configuration from that of a conventional technique, and a method for manufacturing the thermal switching element.

A thermal switching element of the present invention includes a first electrode, a second electrode, and a transition body arranged between the first electrode and the second electrode. The transition body includes a material that causes an electronic phase transition by application of energy. The thermal conductivity between the first electrode and the second electrode is changed by the application of energy to the transition body.

A method for manufacturing a thermal switching element of the present invention is directed to a thermal switching element that includes a first electrode, a second electrode, a transition body arranged between the first electrode and the second electrode, and an insulator arranged between the transition body and the second electrode. The transition body includes a material that causes an electronic phase transition by application of energy. The insulator is formed of a vacuum. The thermal conductivity between the first electrode and the second electrode is changed by the application of energy to the transition body. The method includes (I) producing a space between the second electrode and the transition body by locating the second electrode and a laminate including the transition body and the first electrode at a predetermined distance apart so that the second electrode faces the transition body, and (II) forming an insulator between the second electrode and the transition body by maintaining the space under vacuum.

The method for manufacturing a thermal switching element of the present invention also may be referred to as a method for manufacturing the thermal switching element as described above that further includes an insulator, and the insulator is formed of a vacuum and arranged between the transition body and the second electrode.

A method for manufacturing a thermal switching element of the present invention is directed to a thermal switching element that includes a first electrode, a second electrode, a transition body arranged between the first electrode and the second electrode, and an insulator arranged between the transition body and the second electrode. The transition body includes a material that causes an electronic phase transition by application of energy. The insulator is formed of a vacuum. The thermal conductivity between the first electrode and the second electrode is changed by the application of energy to the transition body. The method may include (i) producing a space between the second electrode and the transition body by locating the second electrode and the transition body at a predetermined distance apart, (ii) forming an insulator between the second electrode and the transition body by maintaining the space under vacuum, and (iii) arranging the first electrode so that the transition body is located between the second electrode and the first electrode.

A method for manufacturing a thermal switching element of the present invention is directed to a thermal switching element that includes a first electrode, a second electrode, a transition body arranged between the first electrode and the second electrode, and an insulator arranged between the transition body and the second electrode. The transition body includes a material that causes an electronic phase transition by application of energy. The insulator is formed of a vacuum. The thermal conductivity between the first electrode and the second electrode is changed by the application of energy to the transition body. The method may include (A) forming a laminate by layering the first electrode, the transition body, a precursor made of a material that is mechanically broken more easily than the transition body, and the second electrode in the indicated order, (B) producing a space between the second electrode and the transition body by extending the laminate in the layering direction of the laminate so as to break the precursor and removing the broken precursor, and (C) forming an insulator between the second electrode and the transition body by maintaining the space under vacuum.

### BRIEF DESCRIPTION OF THE DRAWINGS

FIGS. 1A and 1B are schematic views showing an example of a thermal switching element of the present invention.

FIG. 2 is a schematic cross-sectional view showing another example of a thermal switching element of the present invention.

FIG. 3 is a schematic view showing an example of the structure of an insulator that can be used in a thermal switching element of the present invention.

FIG. 4 is a schematic view showing yet another example of a thermal switching element of the present invention.

FIG. 5 is a schematic view showing an example of a method for applying energy to a thermal switching element of the present invention.

FIG. 6 is a schematic view showing still another example of a thermal switching element of the present invention.

FIGS. 7A and 7B are schematic views showing another example of a method for applying energy to a thermal switching element of the present invention.

FIGS. 8A and 8B are schematic views showing an example of a flux guide that can be used in a thermal switching element of the present invention.

FIG. 9 is a schematic view showing yet another example of a method for applying energy to a thermal switching element of the present invention.

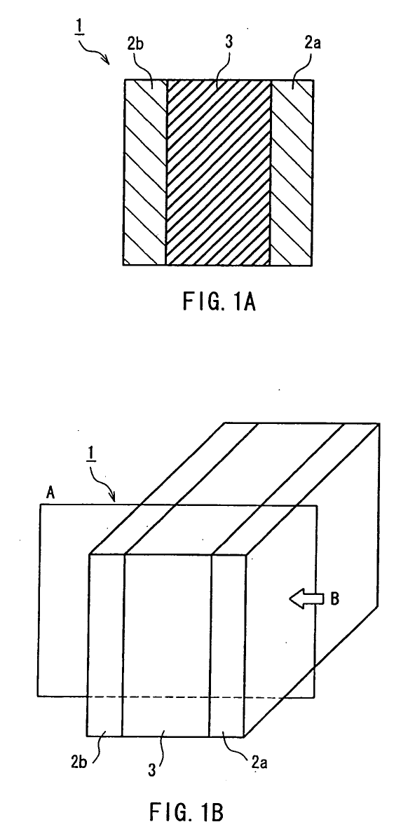

FIGS. 1OA and lOB are schematic views showing still another example of a method for applying energy to a thermal switching element of the present invention.

FIG. 11 is a schematic view showing another example of a flux guide that can be used in a thermal switching element of the present invention.

FIGS. 12A and 12B are schematic views showing still another example of a method for applying energy to a thermal switching element of the present invention.

FIG. 13 is a schematic view showing still another example of a method for applying energy to a thermal switching element of the present invention.

FIGS. 14A and 14B are schematic views showing still another example of a method for applying energy to a thermal switching element of the present invention.

FIG. 15 is a schematic view showing still another example of a method for applying energy to a thermal switching element of the present invention.

FIG. 16 is a schematic view showing still another example of a method for applying energy to a thermal switching element of the present invention.

FIG. 17 is a schematic view showing an example of a method for manufacturing a thermal switching element of the present invention.

FIGS. 18A to 18D are schematic flow charts showing another example of a method for manufacturing a thermal switching element of the present invention.

FIG. 19 is a schematic view showing still another example of a thermal switching element of the present invention.

FIGS. 20A to 20E are schematic flow charts showing an example of a method for manufacturing the thermal switching element in FIG. 19.

FIG. 21 is a schematic view showing still another example of a thermal switching element of the present invention.

FIG. 22 is a schematic view showing still another example of a thermal switching element of the present invention.

FIG. 23 is a schematic view showing still another example of a thermal switching element of the present invention and a method for applying energy to the thermal switching element.

FIG. 24 is a schematic view showing still another example of a thermal switching element of the present invention.

### DESCRIPTION OF THE PREFERRED EMBODIMENTS

Hereinafter, embodiments of the present invention will be described with reference to the drawings. In the following embodiments, the identical elements are denoted by the same reference numerals, and the description may not be repeated.

FIGS. 1A and 1B show an example of a thermal switching element of the present invention. A thermal switching element 1 in FIGS. 1A and 1B includes an electrode 2a, an electrode 2b, and a transition body 3 arranged between the electrodes 2a and 2b. The transition body 3 includes a material (also referred to as “phase transition material” in the following) that causes an electronic phase transition by the application of energy. The thermal conductivity between the electrodes 2a and 2b is changed by the application of energy to the transition body 3. The transition body 3 serves as a heat transfer control material as well as a heat conductive medium. With this configuration, the thermal switching element 1 can control heat transfer by the application of energy. Moreover, the thermal switching element 1 of the present invention can control heat transfer without using any coolant such as chlorofluorocarbon. Further, it is possible not only to improve the efficiency compared with a Peltier element (a conventional thermoelectric element), but also to reduce the energy consumption of a thermal device incorporating the thermal switching element of the present invention as a whole. FIG. 1A is a schematic cross-sectional view of the thermal switching element 1 in FIG. 1B, taken along the plane A in FIG. 1B.

In the thermal switching element 1 of the present invention, the thermal conductivity can be changed in any form by the application of energy to the transition body 3. For example, when energy is applied to the transition body 3, heat transfer between a pair of electrodes 2a and 2b may become easier or more difficult than that before the application of energy. In other words, the thermal switching element 1 may have two states: a state in which heat moves relatively easily between the electrodes 2a and 2b(i.e., heat transfer in the transition body 3 is relatively easy); and a state in which heat moves with relative difficulty between the electrodes 2a and 2b (i.e., heat transfer in the transition body 3 is relatively difficult). When the former is identified as an ON state and the latter is identified as an OFF state, the thermal switching element 1 may be in either ON or OFF state by applying energy to the transition body 3. The thermal conductivity is preferably as small as possible in the OFF state. A change in thermal conductivity between the electrodes 2a and 2b with the application of energy to the transition body 3 may be in either linear or nonlinear form. For example, the applied energy with which the thermal conductivity changes may have a threshold value. Alternatively, a change in thermal conductivity may exhibit hysteresis for energy applied to the transition body 3. These forms of changes in thermal conductivity can be adjusted, e.g., by selecting a phase transition material included in the transition body 3. In this specification, the thermal switching element is in the ON state when heat transfer is relatively easy, while the thermal switching element is in the OFF state when heat transfer is relatively difficult.

The electronic phase transition is a phase transition where the state of electrons in a substance changes regardless of the presence or absence of a structural phase transition (any change.in structure itself of the substance, e.g., from solid to liquid). Therefore, the transition body 3 also may include a material whose electronic state is changed by the application of energy. The thermal switching element 1 of the present invention can control heat transfer by changing the state of electrons in the transition body 3.

The heat conduction of a solid material is expressed generally by the sum of a component due to phonon contribution and a component due to electron conduction contribution. The component due to phonon contribution can be a thermal component that is conducted by the lattice vibration of a substance, and the degree of conduction of the thermal component is referred to as lattice thermal conductivity. The component due to electron conduction contribution can be a thermal component that is conducted by the movement of electrons in a substance, and the degree of conduction of the thermal component is referred to as electronic thermal conductivity. The electronic phase transition involves a change in the state of electrons in a substance. Therefore, the thermal switching element 1 of the present invention also can be regarded as an element in which at least the electronic thermal conductivity of the transition body 3 is changed by the application of energy. Such a change in electronic thermal conductivity of the transition body 3 with the application of energy is used to control heat transfer between the electrodes 2a and 2b.

An insulator-metal transition is an example of the electronic phase transition. Thus, the transition body 3 may cause an insulator-metal transition by the application of energy in the thermal switching element 1 of the present invention. After the transition body 3 has changed to the metallic state, the whole of the transition body 3 is not necessarily a metallic phase, but part of the transition body 3 may include a metallic phase. In view of the characteristics of the thermal switching element, when the transition body 3 undergoes the insulator-metal transition, the thermal conductivity of the transition body 3 in the insulator state is preferably as small as possible. That is, the lattice thermal conductivity of the transition body 3 is preferably as small as possible. The smallest possible lattice thermal conductivity of the transition body 3 is preferred even if the transition body 3 does not cause an insulator-metal transition.

As described above, the thermal switching element 1 of the present invention can control heat transfer via electrons by applying energy to the transition body 3. In this case, the heat transfer may be controlled via thermions. That is, when heat moves relatively easily between the electrodes 2a and 2b (i.e., heat transfer in the transition body 3 is relatively easy: ON state), it may be relatively easy for thermions to move in the transition body 3. When heat moves with relative difficulty between the electrodes 2a and 2b (i.e., heat transfer in the transition body 3 is relatively difficult: OFF state), it may be relatively difficult for thermions to move in the transition body 3. In the thermal switching element 1 of the present invention, such a change in movement of the thermions is attributed to the electronic phase transition caused by the application of energy to the transition body 3.

In this embodiment, the thermions mean “electrons that involve heat transfer”. In many cases, thermions generally indicate electrons emitted from the surface of a heated metal or semiconductor. The electrons passing through the transition body 3 of the thermal switching element 1 of the present invention are not limited to the general thermions, but can be electrons that involve heat transfer. The thermal switching element of the present invention was not achieved until the following were taken into consideration: the transition body arranged between the electrodes to control heat transfer by the application of energy, the combination of materials for each layer such as the transition body, the configuration or arrangement of each layer, and the like.

Therefore, the thermal switching element of the present invention is considered quite different in configuration from a superconducting switch as disdosed, e.g., in JP 01(1989)-216582 A. The superconducting state described in JP 01(1989)-216582 A is physically similar to the superfluid state and has ideal heat insulation properties. Thus, it may be difficult for the superconducting switch of the above document to control heat transfer, which can be performed by the thermal switching element of the present invention. In contrast, the transition body 3 of the thermal switching element 1 of the present invention may be in the normal conducting state (i.e., not in the superconducting state) when electrons move relatively easily.

In the thermal switching element 1 of the present invention, energy applied to the transition body 3 is not particularly limited. For example, at least one selected from electric energy, light energy, mechanical energy, magnetic energy, and thermal energy may be applied to the transition body 3. The choice of which energy to use depends on the type of a phase transition material included in the transition body 3. Two or more types of energy may be applied to the transition body 3. In this case, it is possible to apply the two or more types of energy either simultaneously or in the order of their types as needed. For example, electric energy may be applied first to the transition body 3, followed by light energy, mechanical energy, or the like. There is no particular limitation to a method for applying each type of energy.

The application of electric energy to the transition body 3 may be performed, e.g., by injecting electrons or holes (positive holes) into the transition body 3 or by inducing electrons or holes in the transition body 3. The injection or induction of electrons or holes may be performed, e.g., by producing a potential difference between the electrodes 2a and 2b, and specifically, e.g., by applying a voltage between the electrodes 2a and 2b. More specific examples of the configuration to apply electric energy and examples of the configuration to apply other types of energy will be described later.

The shape or size of the thermal switching element 1 is not particularly limited and may be determined arbitrarily in accordance with the necessary characteristics of the thermal switching element 1. As shown in FIGS. 1A and 1B, e.g., the electrode 2a , the transition body 3, and the electrode 2b may be arranged in layers. For this layered structure, the element area of the thermal switching element 1 is, e.g., in the range of 1×10² nm² to 1×10² cm². The element area is an area of the element as seen from the direction in which each layer is laminated (e.g., the direction of the arrow B in FIG. 1B).

The transition body 3 of the thermal switching element 1 of the present invention will be described below. The transition body 3 may include, e.g., any of the following materials as a phase transition material.

The transition body 3 may include, e.g., an oxide with a composition expressed by AₓD_{y}O_{z}, where A is at least one element selected from the group consisting of alkali metal (Group Ia), alkaline-earth metal (Group IIa), Sc, Y, and rare-earth element (La, Ce, Pr, Nd, Sm, Eu, Gd, Tb, Dy, Ho, and Er), D is at least one transition element selected from the group consisting of Groups IIIa, IVa, Va, VIa, VIIa, VIII, and Ib, and O is oxygen. The groups of elements are described based on IUPAC (1970) in this specification. According to IUPAC (1989), the at least one transition element is selected from Groups 3, 4, 5, 6, 7, 8, 9, 10, and 11. The oxide generally has a crystal structure in which the element D is located basically at a central position in a unit cell of the corresponding crystal lattice, and the atom at the central position is surrounded by a plurality of oxygen atoms.

There is no particular limitation to x, y, and z as long as they are positive numbers. Above all, x, y, and z are preferably numerical values that satisfy the following combinations. The oxides can be classified into a plurality of categories depending on the combinations. The transition body 3 may include an oxide that belongs to each of the categories. The values of x, y, and z of an oxide that belongs to each of the categories do not necessarily satisfy fully the following values including examples). For example, an oxide may be partially deficient in oxygen or may be doped with a small amount of elements (e.g., the elements of Groups IIa to Vb) other than the elements A and D. The following categories are not established as common knowledge in the technical field of the present invention, but provided for convenience to make a clear explanation of the oxides.

Category 1

In this category, x, y, and z satisfy x=n+2, y=n+1, and z=3n+4, where n is 0, 1, 2, or 3.

Examples of the oxide belonging to this category include oxides having an xyz index of (214) such as Sr₂RuO₄ and (La, Sr)₂CoO₄, and oxides having an xyz index of (327) such as Sr₃Ru₂O₇ and (La, Sr)₃Mn₂O₇. These oxides exhibit a so-called Ruddlesden-Popper structure.

When n=0, this category may include oxides in which the element D is placed at the position of the element A and/or the element A is placed at the position of the element D. Examples of such oxides may be an oxide with a composition expressed by DₓA_{y}O_{z}, and an oxide with a composition expressed by DₓD_{y}O_{z}. Specifically, this category may include, e.g., oxides having a spinel structure such as Mg₂TiO₄, Cr₂MgO₄, and Al₂MgO₄(xyz index (214)), and oxides (xyz index (214)) that do. not contain the element A such as Fe₂CoO₄ and Fe₂FeO₄(i.e., Fe₃O₄).

Category 2

In this category, x, y, andzsatisfy x=n+1, y=n+1, and z=3n+5, where n is 1, 2, 3, or 4. Examples of the oxide belonging to this category include oxides having the partial intercalation of oxygen.

Category 3

In this category, x, y, and z satisfy x=n, y=n, and z=3n, where n is 1, 2, or 3. When n=1, examples of the oxide belonging to this category include oxides having a perovskite crystal structure such as SrTiO₃, BaTiO₃, KNbO₃, LiNbO₃, SrMnO₃, and SrRuO₃. When n=2, examples of the oxide that belongs to this category include oxides having an xyz index of (226) such as Sr₂FeMoO₆ and SmBaMn₂O₆.

Category 4

In this category, x, y, and z satisfy x=n+1, y=n, and z=4n+1, where n is 1 or 2. When n=1, examples of the oxide belonging to this category include oxides having an xyz index of (215) such as Al₂TiO₅ and Y₂MoO₅. When n=2, examples of the oxide that belongs to this category include oxides such as SrBi₂Ta₂O₉.

Category 5

In this category, x, y, and z satisfy x=0 or 1, y=0 or 1, and z=1, where either x or y is 0. Examples of the oxide belonging to this category include BeO, MgO, BaO, CaO, NiO, MnO, CoO, CuO, and ZnO.

Category 6

In this category, x and y satisfy x=0, 1, or 2, y=0, 1, or 2, where either x or y is 0, and if x is 0, z is obtained by adding 1 to y, and if y is 0, z is obtained by adding 1 to x. Examples of the oxide belonging to this category include TiO₂, VO₂, MnO₂, GeO₂, CeO₂, PrO₂, SnO₂, Al₂O₃, V₂O₃, Ce₂O₃, Nd₂O₃, Ti₂O₃, Sc₂O₃, and La₂O₃.

Other Categories

When x=0 or 2, y=0 or 2, and z=5, examples of the oxide may be Nb₂O₅, V₂O₅, and Ta₂O₅, where either x or y is 0.

The transition body 3-may include two or more types of the above oxides. For example, the transition body 3 may include oxides having a superlattice as a combination of a structural unit cell and a small unit cell of the oxides with different values of n in the same category. Specific categories may be, e.g., the category 1 (the oxides having a Ruddlesden-Popper structure) and the category 2 (the oxides having the intercalation of oxygen). The crystal lattice structure of such oxides having a superlattice is formed so that, e.g., oxygen octahedral layers of a single or plural elements D are separated by at least one block layer including the element A and oxygen.

The transition body 3 may include a strongly correlated electron material, e.g., a Mott insulator.

The transition body 3 may include a magnetic semiconductor. As a base material of the magnetic semiconductor, e.g., a compound semiconductor can be used. Specifically, examples of the compound semiconductor include the following: compound semiconductors of Groups I-V, I-VI, II-IV, II-V, II-VI, III-V, III-VI, IV-IV, I-III-VI, I-V-VI, II-III-VI, and II-IV-V such as GaAs, GaSe, AlAs, InAs, AIP, AlSb, GaP, GaSb, InP, InSb, In₂Te₃, ZnO, ZnS, ZnSe, ZnTe, CdSe, CdTe, CdSb, HgS, HgSe, HgTe, SiC, GeSe, PbS, Bi₂Te₃, Sb₂Se₃, Mg₂Si, Mg₂Sn, Mg₃Sb₂, TiO₂, CuInSe₂, CuHgIn₄, ZnIn₂Se₄, CdSnAs₂, AgInTe₂, AgSbSe₂, GaN, AlN, GaAlN, BN, AlBN, and GaInNAs. Any of these compound semiconductors is used as a base material, to which at least one element selected from Groups IVa to VIII and IVb is added, thereby providing a magnetic semiconductor.

Alternatively, it is also possible to use a magnetic semiconductor with a composition expressed by Q¹Q²Q³, where Q¹ is at least one element selected from Sc, Y, a rare earth element (La, Ce, Pr, Nd, Sm, Eu, Gd, Tb, Dy, Ho, or Er), Ti, Zr, Hf, V, Nb, Ta, Cr, Ni, and Zn, Q² is at least one element selected from V, Cr, Mn, Fe, Co, and Ni, and Q³ is at least one element selected from C, N, O, F, and S. The composition ratio of the elements Q¹, Q², and Q³ is not particularly limited.

Alternatively, it is also possible to use a magnetic semiconductor with a composition expressed by R¹R²R³, where R¹ is at least one element selected from B, Al, Ga, and In, R² is at least one element selected from N and P, and R³ is at least one element selected from Groups IVa to VIII and IVb. The composition ratio of the elements R¹, R², and R³ is not particularly limited.

Alternatively, it is also possible to use a magnetic semiconductor with a composition expressed by ZnOR³, where R³ is the same as that described above, Zn is zinc, and O is oxygen. The composition ratio of the elements Zn, 0, and R³ is not particularly limited.

Alternatively, it is also possible. to use a magnetic semiconductor with a composition expressed by TOR³, where T is at least one element selected from Ti, Zr, V, Nb, Fe, Ni, Al, In, and Sn, R³ is the same as that described above, and O is oxygen. The composition ratio of the elements T, O, and R³ is not particularly limited.

The transition body 3 may include a material that causes a transition between metamagnetism and ferromagnetism by an externally applied electric field. For example, La (Fe, Si) or FeRh can be used. In this case, the application of electric energy allows the transition body 3 to cause an electronic phase transition.

When thermal energy is applied to the transition body 3 to cause an electronic phase transition, the transition body 3 may include, e.g., GaSb, InSb, InSe, Sb₂Te₃, GeTe, Ge₂Sb₂Te₅, InSbTe, GeSeTe, SnSb₂Te₄, InSbGe, AgInSbTe, (Ge, Sn) SbTe, GeSb (Se, Te), or Te₈₁Ge₁₅Sb₂S₂.

The shape or size of the transition body 3 is not particularly limited and may be determined arbitrarily in accordance with the necessary characteristics of the thermal switching element 1. When the transition body 3 is formed in a layer as shown in FIGS. 1A and 1B, the thickness of the transition body 3 is, e.g., in the range of 0.3 nm to 100 μm, and preferably in the range of 0.3 nm to 1 μm. The area (e.g., the area as seen from the direction of the arrow B in FIG. 1B) of the transition body 3 may be determined arbitrarily in accordance with the necessary element area of the thermal switching element 1. The transition body 3 may include a plurality of layers, and the thickness or material of each layer may be determined arbitrarily in accordance with the necessary characteristics of the transition body 3.

A material used for the electrodes 2a, 2b is not particularly limited as long as it is a conductive material. For example, a material having a linear resistivity of not more than 100 μΩ cm, specifically Cu, Al, Ag, Au, Pt, or TiN, can be used. If necessary, a semiconductor material also can be used. It is preferable that the semiconductor material has a small work function. The shape or size of the electrodes 2a, 2b is not particularly limited and maybe determined arbitrarily in accordance with the necessary characteristics of the thermal switching element 1.

Next, configuration examples of a thermal switching element of the present invention will be described.

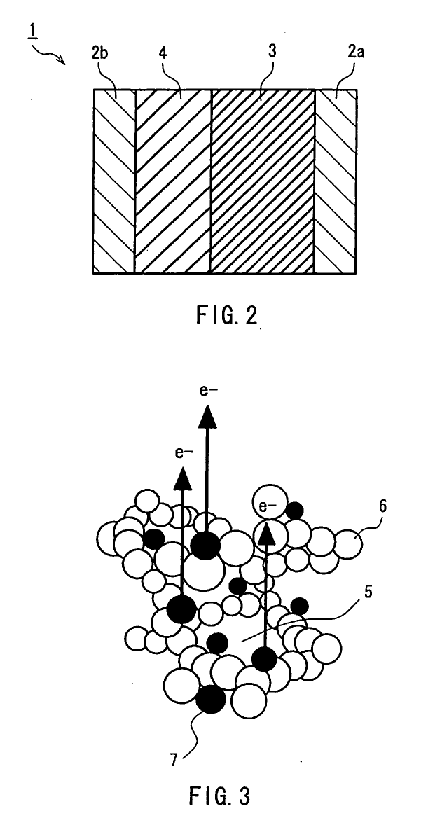

FIG. 2 is a schematic cross-sectional view showing another example of the thermal switching element of the present invention. Compared with the thermal switching element 1 in FIGS. 1A and 1B, a thermal switching element 1 in FIG. 2 further includes an insulator 4 that is arranged between the transition body 3 and the electrode 2b. In this thermal switching element 1, the thermal conductivity of the insulator 4 is small. Therefore, when the transition body 3 is in the OFF state, the thermal conductivity of the thermal switching element 1 as a whole can be reduced further. Thus, the thermal switching element 1 can achieve higher efficiency. The thermal switching element 1 including the insulator 4 also can serve as a cooling element that conducts heat from one electrode to the other electrode, which will be described later.

The thermal conductivity of the insulator 4 is preferably smaller than that of the transition body 3 in the OFF state (e.g., when the transition body 3 undergoes an insulator-metal transition, it is in the insulator state). Thus, the thermal switching element 1 can achieve higher efficiency.

In the thermal switching element 1 including the insulator 4 as shown in FIG. 2, the gap potential that is sensed by electrons (thermions) transported between the electrodes 2a and 2b may vary significantly with the electron phase transition of the transition body 3. For example, when heat transfer is relatively easy, i.e., the transition body 3 is in the ON state (e.g., when the transition body 3 undergoes an insulator-metal transition, it includes a metallic phase), thermions are transported from the end portion of the transition body 3 that faces the insulator 4 to the electrode 2b through the insulator 4. To ensure the transport of thermions, the thickness of the insulator 4 may be, e.g., not more than 50 nm, and preferably not more than 15 nm in view of heat transfer efficiency. The lower limit of the thickness of the insulator 4 is not particularly limited and may be, e.g., not less than 0.3 nm. The shape of the insulator 4 is not particularly limited and may be determined arbitrarily in accordance with the shapes of the transition body 3 and the electrode 2b. In the thermal switching element 1 including the insulator 4, thermions are transported from the electrode 2a (or the transition body 3) to the electrode 2b across the insulator 4. It is considered that the thermions are transported to the electrode 2b via the insulator 4, e.g., by tunnel transport, ballistic transport, or so-called thermionic transport. The transport method differs depending on the material used for the insulator 4, the thickness (i.e., the gap potential) of the insulator 4, or the like. In other words, the transport method also can be controlled, e.g., by controlling the material or thickness of the insulator 4.

The insulator 4 may be formed, e.g., of a vacuum. When the insulator 4 is formed of a vacuum, the configuration of the element can be simplified. A method for producing the thermal switching element including the insulator 4 formed of a vacuum will be described later. In this case, a vacuum may be an atmosphere in which the pressure.is, e.g., about 1 Pa or less. For the insulator 4 formed of a vacuum, thermions may be transported basically by thermionic transport. Depending on the thickness of the insulator 4, there may be some thermions transported by tunnel transport.

A general solid insulating material, e.g., ceramics such as an oxide or resin, can be used as the insulator 4. In this case, it is preferable that an amorphous or microcrystalline insulator is used as the insulator 4. In this specification, the microcrystalline state indicates that crystal grains having an average grain size of not more than 10 nm are dispersed in an amorphous base. When a solid insulator is used, the insulator 4 is preferably formed of a tunnel insulator. For the insulator 4 formed of a tunnel insulator, thermions that carry heat may be transported by tunnel transport. To form the tunnel insulator, e.g., a general material with tunnel insulating properties can be used. Specific examples of the material include an oxide, nitride, and oxynitride of Al, Mg, or the like. The thickness of the insulator 4 formed of a tunnel insulator is, e.g., in the range of 0.5 nm to 50 nm, and preferably in the range of 1 nm to 20 nm.

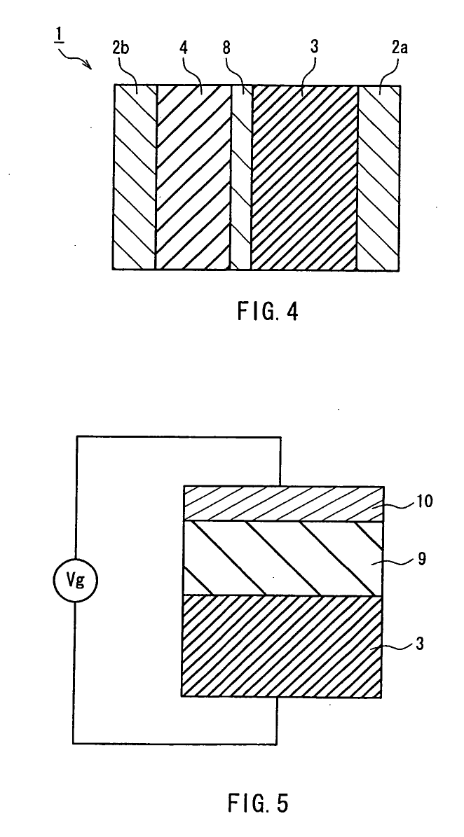

As the insulator 4, e.g., an inorganic polymer material also can be used. Examples of the inorganic polymer material include a silicate material and aluminum silicate material. FIG. 3 shows an example of the structure of the inorganic polymer material. As shown in FIG. 3, the inorganic polymer material such as a silicate material or aluminum silicate material has a porous structure. Therefore, the inorganic polymer material includes a myriad of hollow regions 5 despite being formed as a solid. The average diameter of the hollow regions 5 is smaller than the mean free path of air, and the mobility of gas inside the hollow regions 5 is substantially small, so that it is difficult for the inorganic polymer material to conduct heat. Thus, the inorganic polymer material can be used as it is for the insulator 4. Alternatively, e.g., the hollow regions 5 may be filled with gas having smaller thermal conductivity or may be formed of a vacuum, thereby further reducing the thermal conductivity of the insulator 4.

The inorganic polymer material in FIG. 3 will be described in detail below. The inorganic polymer material in FIG. 3 includes base materials 6 that form the whole framework. The base materials 6 are particles having an average particle diameter of about several nm and form the framework of the porous structure by constituting a three dimensional network. The inorganic polymer material includes a myriad of continuous hollow regions 5 having an average diameter of about several nm to several tens of nm while maintaining the shape as a solid by the framework made up of the base materials 6. When the insulator 4 with this porous structure is arranged as shown in FIG. 2, and a voltage is applied between the electrodes 2a and 2b while the transition body 3 is in the ON state (or the transition body 3 may be in the ON state by applying a voltage between the electrodes 2a and 2b), an electric field is concentrated on the framework made up of the base materials 6. This electric field concentration allows thermions to be supplied efficiently from the electrode or the transition body into the insulator 4, so that the supplied thermions are transported inside the insulator 4 by radiative transport. In this case, the transport of the thermions is considered mainly due to ballistic transport. The effect of the electric field concentration becomes prominent by providing the insulator 4 with the porous structure as shown in FIG. 3, and a voltage applied between the electrodes 2a and 2b for transporting the thermions can be reduced compared with the insulator 4 that does not have the porous structure as shown in FIG. 3.

For the inorganic polymer material in FIG. 3, part of the supplied thermions may be scattered by a solid-phase region such as the base materials 6 that form the porous structure, and thus lose energy. However, the size of the solid-phase region is an average of about several nm. Therefore, most of the supplied thermions can be used for heat transfer.

The inorganic polymer material in FIG. 3 further includes electron emission materials 7 having an average particle diameter that is approximately equal to or not more than the average diameter of the hollow regions 5. The electron emission materials 7 are dispersed in the inorganic polymer material so as to be in contact with the base materials 6. In the inorganic polymer material including the electron emission materials 7, even if part of the thermions are scattered by the solid-phase region, the scattered thermions are transported to the electron emission materials 7 and re-emitted, and therefore can be used for heat transfer again. The same is true in the case where the re-emitted thermions are scattered further by the solid-phase region. Thus, the thermal switching element 1 can achieve higher efficiency. The electron emission materials 7 preferably have a small work function. Specifically, e.g., a carbon material, Cs compound, or alkaline-earth metal compound can be used. The average particle diameter of the electron emission materials 7 is in the range of about several nm to several tens of nm. The mark “e⁻” in FIG. 3 represents that the electrons are re-emitted.

The insulator 4 is not limited to the inorganic polymer material and may be an insulating material that includes the similar hollow regions of, e.g., continuous or separate voids. Such an insulating material can provide the effect comparable to that of the inorganic polymer material. The insulating material can be produced, e.g., by a method in which powder is prepared as a base material and then fired, chemical foaming, physical foaming, or sol-gel process. However, the insulating material preferably includes a myriad of voids having an average diameter of about several nm to several tens of nm. Iike the inorganic polymer material, the insulating material also may include electron emission materials, and thus can provide the effect comparable to that of the inorganic polymer material.

Specifically, e.g., dried gel produced by the sol-gel process may be used. The dried gel is a nano-porous body that includes a framework made up of particles having an average particle diameter of about several nm to several tens of nm and continuous hollow regions having an average diameter of about not more than 100 nm. A preferred material for the gel is, e.g., a semiconductor material or insulating material in view of the efficient electric field concentration, and particularly silica (silicon oxide) is suitable. A method for producing a porous silica gel, which is the dried gel including silica, will be described later.

FIG. 4 shows yet another example of a thermal switching element of the present invention. Compared with the thermal switching element 1 in FIG. 2, a thermal switching element 1 in FIG. 4 further includes an electrode 8 that is arranged between the transition body 3 and the insulator 4. With this configuration, the thermal switching element 1 can achieve higher efficiency.

A material for the electrode 8 may be the same as that for the electrodes 2a, 2b. In particular, a material having a small work function (e.g., not more than 2 eV) relative to the vacuum level is suitable. Specifically, e.g., a Cs compound or alkaline-earth metal compound can be used. The use of such materials allows thermions to be supplied more efficiently to the insulator 4.

The shape or size of the electrode 8 is not particularly limited and may be determined arbitrarily in accordance with the necessary characteristics of the thermal switching element 1. When the electrode 8 is formed in a layer as shown in FIG. 4, the thickness of the electrode 8 may be, e.g., on the order of subnanometer to several μm.

If necessary, another material may be arranged further between each of the layers of the thermal switching element 1 as shown in FIGS. 1, 2, and 4.

Next, a method for applying energy to the transition body of a thermal switching element of the present invention will be described.

FIG. 5 is a schematic view showing an example of a method for applying electric energy to the transition body 3. As shown in FIG. 5, an electrode 10 and an insulator 9 further are provided to apply energy to the transition body 3. The insulator 9 is arranged between the transition body 3 and the electrode 10, thereby applying electric energy to the transition body 3. Specifically, e.g., a voltage Vg may be applied between the electrode 10 and the transition body 3. The application of the voltage Vg allows, e.g., electrons or holes to be injected or induced in the transition body 3, so that energy can be applied to the transition body 3. The injected or induced electrons can be used as they are for thermions to transfer heat.

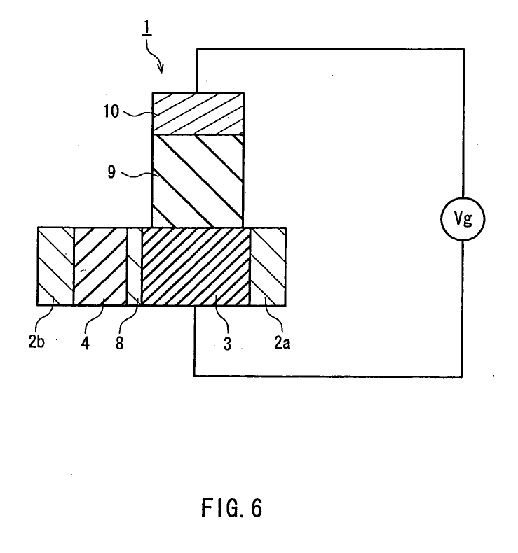

FIG. 6 shows an example of a thermal switching element that includes the structure in FIG. 5. Compared with the thermal switching element 1 in FIG. 4, a thermal switching element 1 in FIG. 6 further includes the insulator 9 and the electrode 10. The insulator 9 and the electrode 10 are arranged so that the insulator 9 is sandwiched between the transition body 3 and the electrode 10. Moreover, the insulator 9 and the electrode 10 are arranged so as not to affect the potential of the electrodes 2a and 2b, and specifically so as to make the direction of the applied voltage Vg substantially perpendicular to the direction of transport of the rmions in the transition body 3. In this thermal switching element 1, the transition body 3 may cause an electronic phase transition by applying the voltage Vg between the transition body 3 and the electrode 10. In the example of FIG. 6, the voltage Vg also may be applied between the electrode 10 and the electrode 2a. A method for applying the voltage Vg is not particularly limited in the thermal switching element of the present invention. For example, a separate voltage application portion may be connected electrically to the thermal switching element of the present invention. When an electric circuit incorporates the thermal switching element of the present invention, the voltage application portion may be included, e.g., in the electric circuit. Moreover, any method or configuration for applying the voltage Vg can be used as long as a potential difference is generated between the regions of the thermal switching element to which a voltage is applied (e.g., between the transition body 3 and the electrode 10 in the example of FIG. 6).

A material for the electrode 10 may be the same as that for the electrodes 2a, 2b. A material for the insulator 9 is not particularly limited as long as it is an insulating material or semiconductor material. For example, the material for the insulator 9 may be a compound of at least one element selected from Groups IIa to VIa including Mg, Ti, Zr, Hf, V, Nb, Ta, and Cr, lanthanide (including La and Ce), and Groups IIb to IVb including Zn, B, Al, Ga, and Si and at least one element selected from F, O, C, N, and B. Specifically, e.g., SiO₂, Al₂O₃, or MgO can be used. As a semiconductor, e.g., ZnO, SrTiO₃, LaAlO₃, AlN, or SiC can be used.

The shape or size of the insulator 9 is not particularly limited. When the insulator 9 is formed in a layer as shown in FIG. 6, the thickness of the insulator 9 may be, e.g., on the order of subnanometer to several μm.

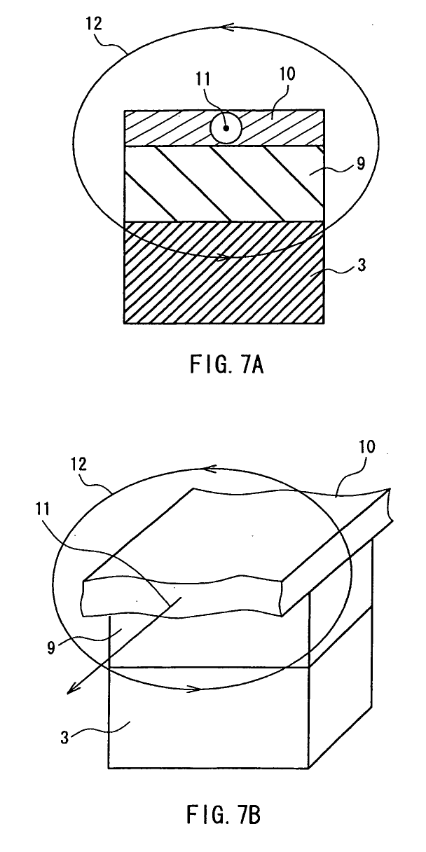

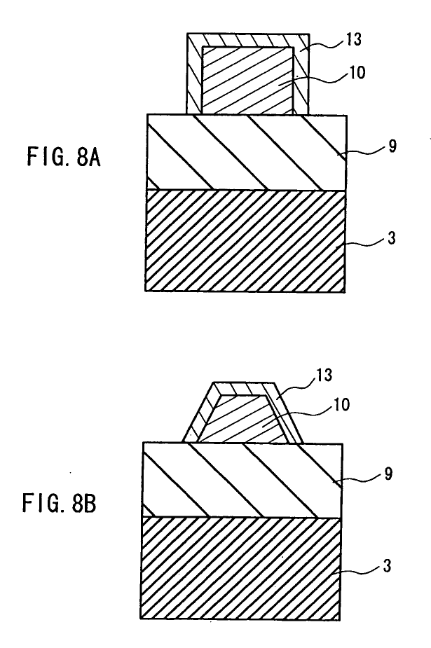

FIGS. 7A and 7B are schematic views showing an example of a method for applying magnetic energy to the transition body 3. The structure in FIGS. 7A and 7B is the same as that in FIG. 5. Instead of the application of the voltage Vg, a current 11 flows through the electrode 10 so as to generate a magnetic field 12, and the magnetic field 12 thus generated is introduced into the transition body 3, thereby applying energy to the transition body 3. FIG. 7A is a schematic cross-sectional view of the structure in FIG. 7B, taken in the same manner as FIG. 1A.

A thermal switching element that includes the structure in FIGS. 7A and 7B may be, e.g., the thermal switching element 1 having the structure in FIG. 6. In such a case, a current flows through the electrode 10 instead of the application of the voltage Vg, and a magnetic field thus generated is introduced into the transition body 3. The transition body 3 may cause an electronic phase transition by allowing the current to flow through the electrode 10. The application of the voltage Vg and the introduction of a magnetic field into the transition body 3 that is generated by a current flowing through the electrode 10 may be performed simultaneously or in a specific order. Both of electric energy and magnetic energy can be applied to the transition body 3. When magnetic energy is applied to the transition body 3, the thickness of the electrode 9 (i.e.; the distance between the electrode 10 and the transition body 3) is, e.g., in the range of several nm to several μm. The insulator 9 need not necessarily be provided as long as the electrode 10 and the transition body 3 are not electrically short-circuited. For example, the electrode 10 and the transition body 3 may be spaced at a distance of about several nm to several μm.

When magnetic energy is applied to the transition body 3, a flux guide for focusing a magnetic field generated in the electrode 10 may be arranged in contact with or in the vicinity of the electrode 10. The flux guide is useful to efficiently introduce the magnetic field 12 into the transition body 3, and thus the thermal switching element can achieve higher efficiency.

The shape of the flux guide is not particularly limited as long as it can focus a magnetic field generated in the electrode 10, and may be determined arbitrarily in accordance with the necessary characteristics of the thermal switching element, the requirements for the manufacturing process, or the like. For example, when the flux guide 13 is combined with the electrode 10, the cross section may be either rectangular (FIG. 8A) or trapezoidal (FIG. 8B) in shape. In the case of a trapezoid as shown in FIG. 8B, more current can flow at the position closer to the transition body 3 into which a magnetic field is introduced. Therefore, the magnetic field can be introduced more efficiently into the transition body 3. In the examples of FIGS. 8A and 8B, the electrode 10 and the flux guide 13 are brought into contact with each other. Although this configuration can introduce a magnetic field into the transition body 3 more efficiently, they are not necessarily brought into contact with each other. FIGS. 8A and 8B do not show the electrode 2a, the electrode 2b, or the like to make the illustration easy to understand. For the same reason, some of the following drawings also do not show those elements. When used actually as a thermal switching element, the electrodes 2a, 2b and, if necessary, the electrode 8 or the insulator 4 may be arranged at any positions.

A material for the flux guide 13 is not particularly limited as long as it can focus a magnetic field generated in the electrode 10, and may be a ferromagnetic material. Specifically, e.g., a soft magnetic alloy film that includes at least one element selected from Ni, Co, and Fe can be used.

It is preferable that the ferromagnetic material used for the flux guide 13 does not have an excessively large coercive force. When the ferromagnetic material with excessively large coercive force is used for the flux guide, there are possibilities that the control of a magnetic field applied to the transition body 3 is reduced due to the magnetization retention of the flux guide 13 itself, and that excessive energy is required to change the magnetization direction of the flux guide 13 itself and thus reduces the efficiency of the thermal switching element.

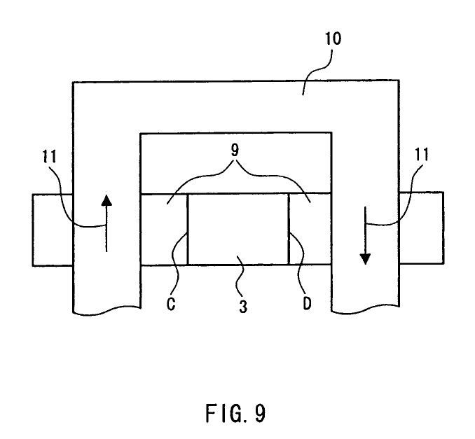

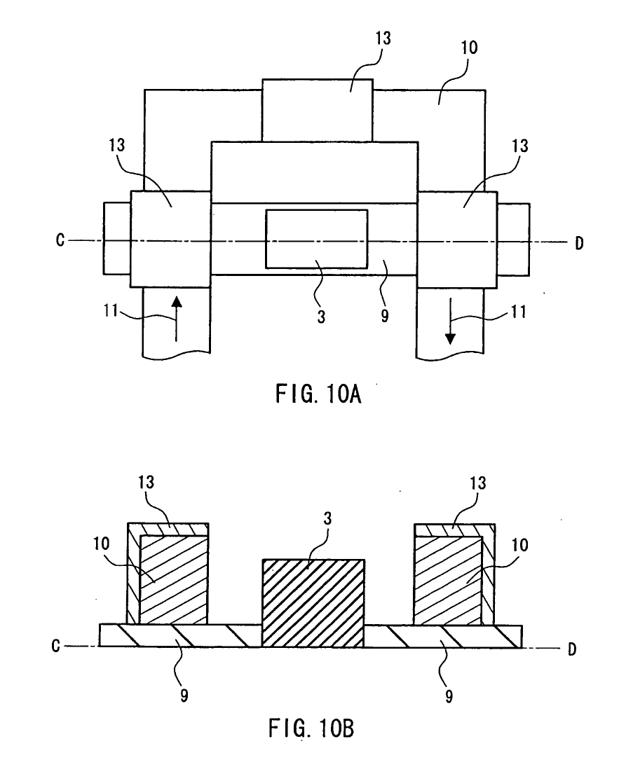

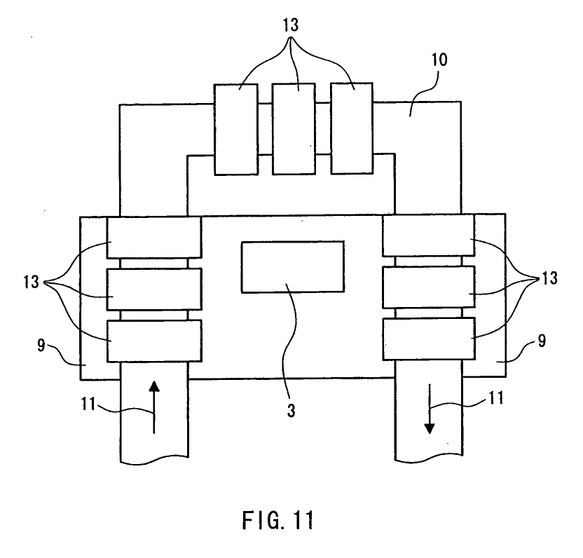

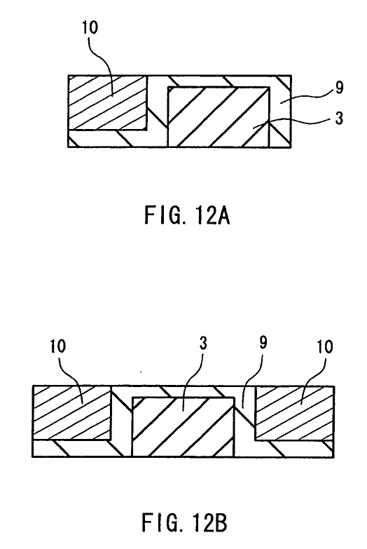

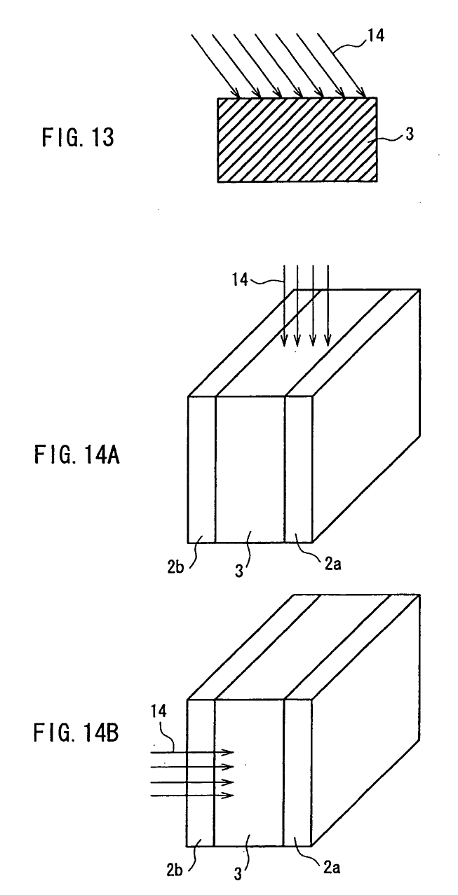

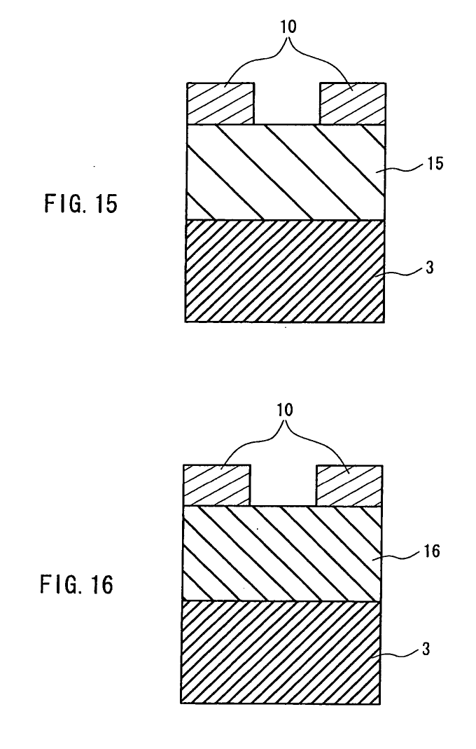

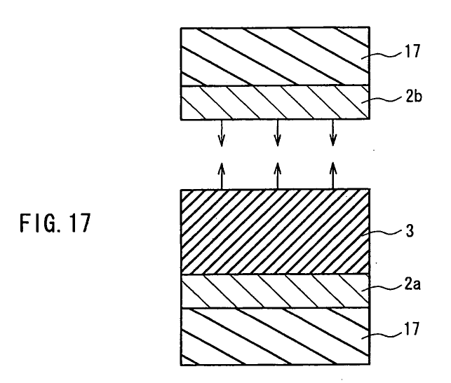

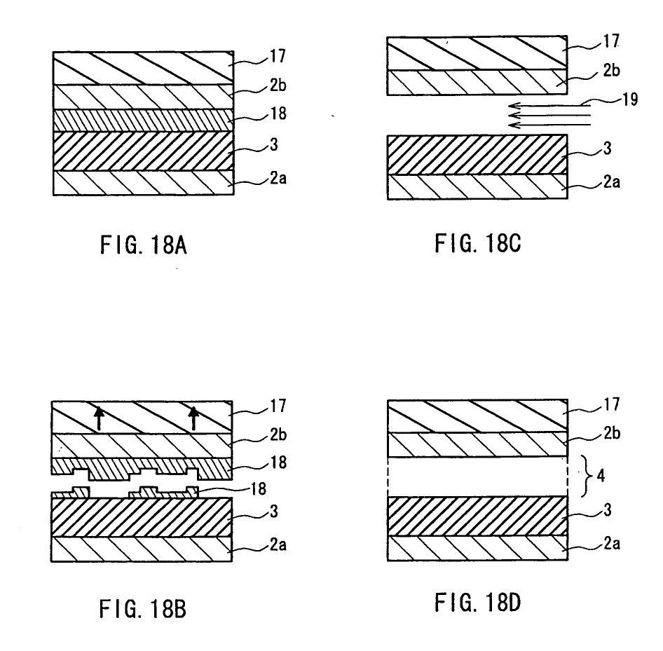

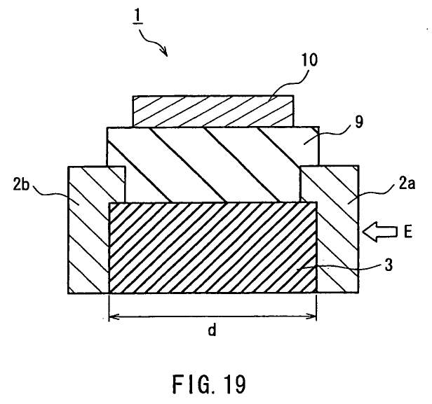

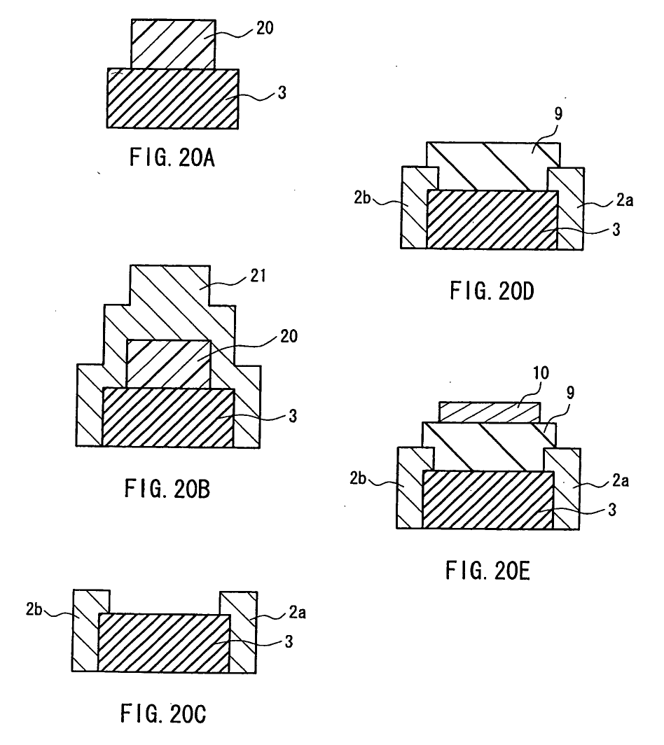

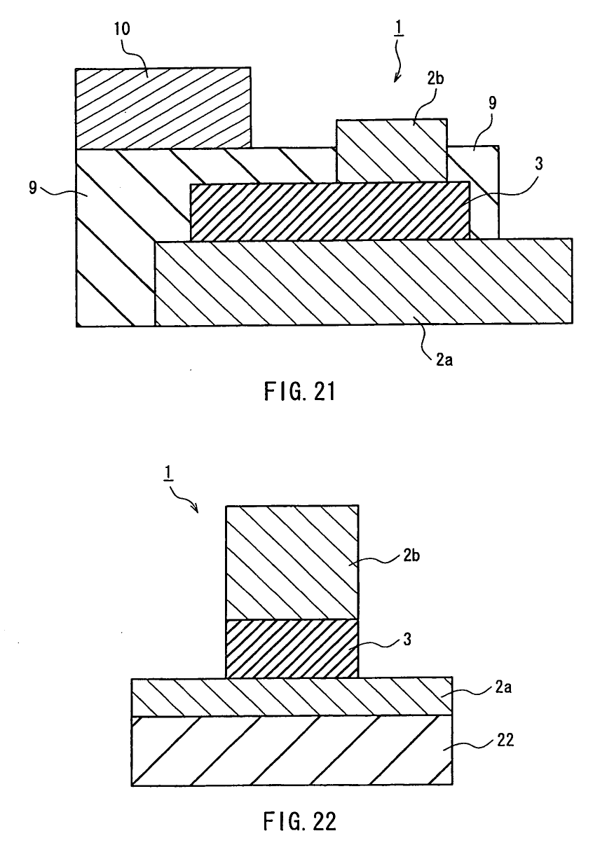

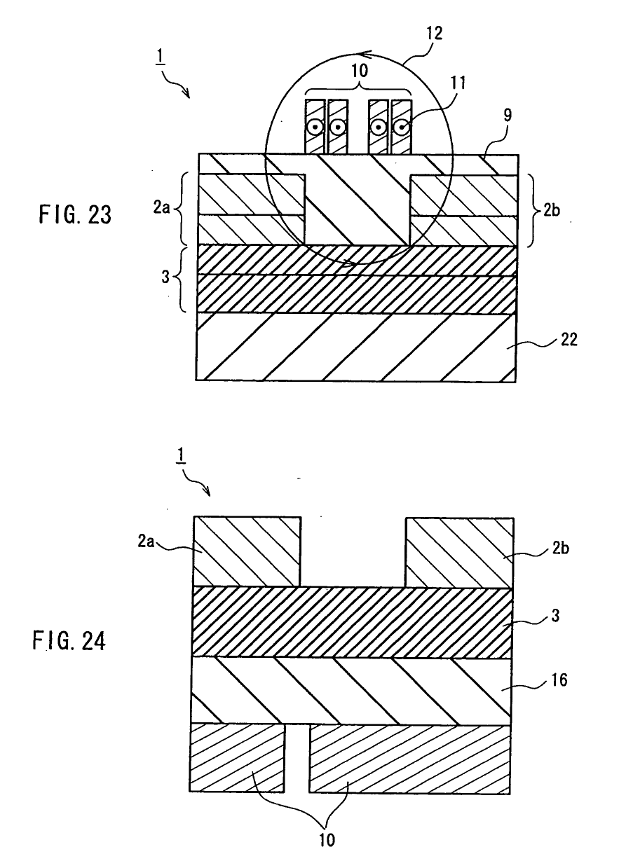

FIG. 9 shows another example of a method for applying magnetic energy to the transition body 3. A structure as shown in FIG. 9 can be used to apply magnetic energy to the transition body 3. In the example of FIG. 9, the electrode 10 is arranged so as to surround the transition body 3. Therefore, the direction of a current flowing through a region of the electrode 10 that faces one side (e.g., the side C in FIG. 9) of the transition body 3 can be opposite to the direction of a current flowing through a region of the electrode 10 that faces the other side (e.g., the side D in FIG. 9) of the transition body 3. Thus, a magnetic field introduced into the transition body 3 can be enhanced, so that the thermal switching element can achieve higher efficiency.

FIGS. 10A and 10B show yet another example of a method for applying magnetic energy to the transition body 3. Compared with the example of FIG. 9, the example of FIGS. 10A and 10B further include flux guides 13. The flux guides 13 are arranged only in the vicinity of the of the transition body 3 into which a magnetic field is introduced. This configuration can introduce a magnetic field more efficiently into the transition body 3 without unnecessarily increasing the coercive force of the flux guides 13. FIG. 10B is a cross-sectional view of FIG. 10A, taken along the direction C-D in FIG. 10A.

When the flux guides 13 are arranged in the vicinity of the transition body 3, the flux guides 13 may be divided as shown in FIG. 11. This configuration can further suppress an increase in coercive force of the flux guides 13 and introduce a magnetic field more efficiently into the transition body 3. The example of FIG. 11 is the same as that of FIGS. 10A and 10B except for the flux guides 13.

FIGS. 12A and 12B shows still another example of a method for applying magnetic energy to the transition body 3. In the example of FIGS. 12A and 12B, a magnetic field can be introduced more efficiently into the transition body 3. This example is suitable particularly when the transition body 3 reacts more readily to a vertical magnetic field.

FIG. 13 is a schematic view showing an example of a method for applying light energy to the transition body 3. As shown in FIG. 13, light 14 may enter the transition body 3 so that light energy is applied to the transition body 3. In this case, the light 14 may enter the transition body 3 either directly as shown in FIG. 14A or via the electrode 2a and/or the electrode 2b as shown in FIG. 14B.

When the light 14 enters the transition body 3 via the electrode 2a and/or the electrode 2b, the electrode (the electrode 2b in FIG. 14B) on which the light 14 is incident should transmit the light 14. Therefore, a material for this electrode may be selected in accordance with the band of the incident light. When the incident light is visible light and/or infrared light, the electrode material may be, e.g., ITO (indium tin oxide) or ZnO. When the incident light is terahertz light, the electrode material may be, e.g., MgO. The degree of transmission of light by the electrode, e.g., the light transmittance of the electrode is not particularly limited and may be determined arbitrarily in accordance with the necessary characteristics of the thermal switching element. Moreover, any method for allowing light to enter the transition body 3 can be used as long as the light can enter the transition body 3. In the thermal switching element 1 in FIG. 4, e.g., the electrode 8 and the insulator 4 also may be made of a material that transmits light entering the transition body 3, and light may enter from the side of the electrode 2b.

FIG. 15 is a schematic view showing an example of a method for applying thermal energy to the transition body 3. In the example of FIG. 15, a heating body 15 is arranged between the transition body 3 and the electrode 10. When a current flows through the electrode 10, it also flows through the heating body 15, and the heating body 15 generates heat. Thus, thermal energy can be applied to the transition body 3. The heating body 15 can be made of a material that generates heat by the passage of a current through it, e.g., a resistor. Moreover, another layer (e.g., an insulator) may be arranged between the heating body 15 and the transition body 3 as needed.

A method for applying thermal energy to the transition body 3 is not particularly limited to the example of FIG. 15. The thermal energy may be applied to the transition body 3, e.g., in such a manner that the heating body 15 as shown in FIG. 10 generates heat by the irradiation of light or radio wave, or the electrode 10 generates heat by the passage of a current through it.

FIG. 16 is a schematic view showing an example of a method for applying mechanical energy to the transition body 3. In the example of FIG. 16, a deformable body 16 is arranged between the transition body 3 and the electrode 10. When a current flows through the electrode 10, the deformable body 16 is deformed. In other words, the deformable body 16 can apply pressure, which is a kind of mechanical energy, to the transition body 3.

The deformable body 16 can be made, e.g., of a piezoelectric material or magnetostrictive material. When the deformable body 16 includes a piezoelectric material, e.g., a current flowing through the electrode 10 may be introduced into the deformable body 16. When the deformable body 16 includes a magnetostrictive material, e.g., a magnetic field generated by a current flowing through the electrode 10 may be introduced into the deformable body 16.

As is evident from the above explanation of a method for applying energy to the transition body 3, a plurality of different types of energy can be applied either simultaneously or in a specific order to the transition body 3 of the thermal switching element of the present invention. For example, the electrode 10 can be used for the application of different types of energy. If necessary, another material may be arranged further between each of the layers as shown in FIGS. 5 to 17.

The thermal switching element 1 of the present invention also can serve as a cooling element that conducts heat from one electrode selected from the electrodes 2a and 2b to the other electrode. For example, when a material that also has the function of an insulator is used for the transition body 3 of the thermal switching element in FIG. 1, the thermal switching element 1 can conduct heat in a predetermined direction. Examples of the material include (Pr, Ca) MnO₃, VO₂, and a layered material such as Bi₂Sr₂Ca₂Cu₃O₁₀. In the case of the layered material, e.g., the interlayer direction may be utilized. Both “the conduction of heat from one electrode to the other electrode” and “the conduction of heat in a predetermined direction” do not exclude the possibility that some heat is conducted in the opposite direction. For example, the heat conduction from the electrode 2a to the electrode 2b and the heat conduction from the electrode 2b to the electrode 2a may be asymmetrical. A phenomenon occurs in which heat is conducted apparently in a predetermined direction.

For the thermal switching element 1 including the insulator 4 as shown in FIG. 2, the conductivity of thermions moving in the direction from the electrode 2a to the electrode 2b and in the direction from the electrode 2b to the electrode 2a can be made asymmetrical, e.g., by controlling the material or thickness of the insulator 4. Therefore, this thermal switching element can serve as an element (i.e., a cooling element) that conducts heat in a predetermined direction. To conduct heat in one direction, the transition body 3 should be in the ON state.

Next, a method for manufacturing a thermal switching element of the present invention will be described.

The individual layers of a thermal switching element can be formed by a general thin film formation process. Examples of the process include various types of sputtering such as pulse laser deposition (PLD), ion beam deposition (IBD), cluster ion beam, RF, DC, electron cyclotron resonance (ECR), helicon, inductively coupled plasma (ICP), and facing target sputtering, molecular beam epitaxy (MBE), and ion plating. In addition to these PVD methods, e.g., CVD, plating, or a sol-gel process can be used as well. When microfabrication is necessary, general methods used for a semiconductor process or a magnetic head fabrication process may be combined. Specifically, e.g., physical or chemical etching techniques such as ion milling, reactive ion etching (RIE), and focused ion beam (FIB), a stepper technique for forming fine patterns, and photolithography with an electron beam (EB) method or the like can be used in combination. Moreover, chemo-mechanical polishing (CMP) or cluster ion beam etching may be used to flatten the surface of each layer (e.g., an electrode) or the like. The individual layers may be formed on a substrate. A material for the substrate is not particularly limited and may be, e.g., Si, SiO₂, or oxide single crystals such as GaAs and SrTiO₃.

The following is an explanation of a method for manufacturing the thermal switching element 1 in which the insulator 4 is in the vacuum state and arranged between the transition body 3 and the electrode 2b, as shown in FIG. 2. In the manufacturing method of this thermal switching element 1, there is no particular limitation to a method for forming the insulator 4 in the vacuum state (also referred to as a vacuum insulating portion) between the transition body 3 and the electrode 2b. For example, a space is produced between the electrode 2b and the transition body 3 by locating the second electrode 2b and the transition body 3 at a predetermined distance apart, and the space is maintained under vacuum, thus forming the insulator 4 between the electrode 2b and the transition body 3. FIG. 17 shows an example of this manufacturing method.

In the example of FIG. 17, the electrode 2b and a laminate including the electrode 2a and the transition body 3 are located at a predetermined distance apart so that the electrode 2b faces the transition body 3, and thus a space is produced between the electrode 2b and the transition body 3 (step (I)). In this case, a vacuum insulating portion can be formed between the electrode 2b and the transition body 3 by maintaining the space under vacuum (step (II)).

The predetermined distance in the step (I) may correspond, e.g., to the necessary thickness of a vacuum insulating portion to be formed. Specifically, the predetermined distance may be, e.g., not more than 50 nm, and preferably not more than 15 nm, as described above. The lower limit of the distance is not particularly limited and may be, e.g., not less than 0.3 nm.

In the step (I), there is no particular limitation to a method in which the electrode 2b and the laminate are located at a predetermined distance apart so that a space is produced between the electrode 2b and the transition body 3. For example, the laminate and/or the electrode 2b may be moved while controlling the distance between them, which can be performed in any manner. Specifically, e.g., a piezoelectric body 17 is arranged to move the electrode 2b and/or the laminate (step (I-a)), and then the piezoelectric body 17 is deformed (step (I-b)), as shown in FIG. 17. The electrode 2b and/or the laminate moves according to the deformation (expansion and/or shrinkage) of the piezoelectric body 17, and thus the laminate and the electrode 2b can be located at a predetermined distance apart. The piezoelectric body 17 may either expand or shrink to put a predetermined distance between the laminate and the electrode 2b. Alternatively, it is also possible to combine the expansion and shrinkage of the piezoelectric body 17.

In the step (I-a), there is no particular limitation to a method for arranging the piezoelectric body 17 as long as the electrode 2b and/or the laminate can be moved. For example, the piezoelectric body 17 may be arranged in contact with the electrode 2b and/or the laminate, as shown in FIG. 17. In FIG. 17, the piezoelectric bodies 17 are in contact with the electrode 2b and the laminate, respectively. Therefore, both of the electrode 2b and the laminate can be moved. Also, the piezoelectric body 17 may be arranged in contact with either the electrode 2b or the laminate. The piezoelectric body 17 can be made of a typical piezoelectric material. If necessary, another layer may be arranged between the piezoelectric body 17 and the electrode 2a and/or between the piezoelectric body 17 and the electrode 2b.

In the step (II), there is no particular limitation to a method for maintaining the space produced in the step (I) under vacuum. For example, the space may be evacuated to create a vacuum and then sealed while keeping the distance between the laminate and the electrode 2b after the step (I). To maintain the space under vacuum, e.g., the whole of the laminate and the electrode 2b may be placed in a vacuum atmosphere. It is also possible to perform the steps (I) and (II) simultaneously. For example, the steps (I) may be performed in a vacuum atmosphere, and a space produced between the laminate and the electrode 2b may be sealed in the same atmosphere. When the step (I) includes two or more processes, the whole of the laminate and the electrode 2b may be placed in a vacuum atmosphere during the step (I). As described above, a vacuum may be an atmosphere in which the pressure is, e.g., about 1 Pa or less.

In the example of FIG. 17, the thermal switching element includes the electrode 2b and the laminate including the electrode 2a and the transition body 3. However, the electrode 2a may be arranged separately from the formation of the vacuum insulating portion. Specifically, this can be carried out, e.g., in the following manner. First, the electrode 2b and the transition body 3 are located at a predetermined distance apart so that the electrode 2b faces the transition body 3, and thus a space is produced between the electrode 2b and the transition body 3 (step (i)). This step also is shown in FIG. 17 by removing the electrode 2a from the element. Next, a vacuum insulating portion is formed between the electrode 2b and the transition body 3 by maintaining the space under vacuum (step (ii)). Then, the electrode 2a is provided so that the transition body 3 is located between the electrodes 2b and 2a (step iii).

The methods for producing the space and the vacuum insulating portion in the steps (i) and (ii) may be the same as those in the steps (I) and (II), respectively. For example, the step (i) may include a step (i-a) in which the piezoelectric body 17 is arranged to move at least one selected from the electrode 2b and the transition body 3 and a step (i-b) in which the piezoelectric body 17 is deformed so that the electrode 2b and the transition body 3 are located at a predetermined distance apart, and a space is produced between the electrode 2b and the transition body 3.

There is no particular limitation to a method for arranging the electrode 2a in the step (iii), and any of the above thin film formation processes can be used. The step (iii) is not necessarily performed after the step (ii) and may be performed, e.g., at any time between the beginning of the step (i) and the end of the step (ii).

FIGS. 18A to 18D show another example of a method for manufacturing the thermal switching element 1 in which the insulator 4 is formed as a vacuum insulating portion and arranged between the transition body 3 and the electrode 2b.

First, a multilayer film that includes the electrode 2a, the transition body 3, the electrode 2b, and a precursor 18 instead of the vacuum insulating portion is formed as shown in FIG. 18A (step (A)). Since the vacuum insulating portion is replaced by the precursor 18, the order of layering in the multilayer film is the electrode 2a, the transition body 3, the precursor 18, and the electrode 2b. In this case, the precursor 18 can be made of a material that is mechanically broken more easily than the transition body 3, e.g., a material that is broken more easily than the transition body 3 when subjected to compressive force or tensile force. In other words, e.g., a material having a smaller strength than that of the transition body 3 can be used. Specifically, examples of the material include Bi, Pb, and Ag. The thickness of the precursor 18 may correspond, e.g., to the necessary thickness of the vacuum insulating portion, and specifically is as described above.

Next, as shown in FIG. 18B, the multilayer film is extended in the layering direction of the multilayer film so as to break the precursor 18. Then, as shown in FIG. 18C, the precursor 18 is removed by blowing gas 19 onto the remaining precursor 18, so that a space is produced between the transition body 3 and the electrode 2b (step (B)).

Subsequently, as shown in FIG. 18D, the space is maintained under vacuum, thereby providing a thermal switching element in which the insulator 4 in the vacuum state is formed between the electrode 2b and the transition body 3 (step (C)). Compared with the method as shown in FIG. 17, this method can facilitate control of the thickness (the distance between the electrode 2b and the transition body 3) of the vacuum insulating portion because the thickness of the vacuum insulating portion can correspond to that of the precursor 18.

There is no particular limitation to a method for forming the multilayer film in the step (A), and any of the above film formation processes can be used.

In the step (B), a method for extending the multilayer film in its layering direction is not particularly limited and may be performed, e.g., by using the piezoelectric body 17 as shown in FIG. 18B. Specifically, the step (B) may include a step (B-a) in which the piezoelectric body 17 is arranged in contact with at least one principal surface of the multilayer film and a step (B-b) in which the piezoelectric body 17 is deformed (expansion and/or shrinkage) so that the multilayer film is extended in the layering direction of the multilayer film, and the precursor 18 is broken.

In the step (B-a), there is no particular limitation to a method for arranging the piezoelectric body 17 as long as the multilayer film can be extended. For example, the piezoelectric body 17 may be arranged in contact with the electrode 2b of the multilayer film, as shown in FIG. 18B. Also, the piezoelectric body 17 may be arranged either on the side of the electrode 2a or on the side of each of the electrodes 2a, 2b. The piezoelectric body 17 can be made of a typical piezoelectric material. If necessary, another layer may be arranged between the piezoelectric body 17 and the electrode 2a and/or between the piezoelectric body 17 and the electrode 2b.

In the step (B-b), the piezoelectric body 17 may either expand or shrink to extend the multilayer film. Alternatively, it is also possible to combine the expansion and shrinkage of the piezoelectric body 17. For example, when the piezoelectric body 17 expands and shrinks so that the amount of expansion is equal to the amount of shrinkage, a space can be produced while maintaining the same distance (between the transition body 3 and the electrode 2b) as the thickness of the precursor 18.

In the step (B), a method for removing the remaining precursor 18 is not particularly limited and may be performed, e.g., by blowing the gas 19 as shown in FIG. 18C. The remaining precursor 18 can be removed not only by blowing gas, but also by spraying liquid. The type of gas is not particularly limited, and any gas that reacts with the precursor 18 can be used.

In the step (C), there is no particular limitation to a method for maintaining the space produced in the step (B) under vacuum. For example, the space may be evacuated to create a vacuum and then sealed while keeping the distance between the transition body 3 and the electrode 2b after the step (B). To maintain the space under vacuum, e.g., the whole of the transition body 3, the electrode 2b, and the electrode 2a may be placed in a vacuum atmosphere. It is also possible to perform the steps (A) and/or (B) and the step (C) simultaneously. For example, the steps (A) and (B) may be performed in a vacuum atmosphere, and a space produced between the transition body 3 and the electrode 2b may be sealed in the same atmosphere. Further, the whole of the transition body 3, the electrode 2a , and the electrode 2b may be placed in a vacuum atmosphere at any time between the beginning of the step (A) and the end of the step (B). As described above, a vacuum may be an atmosphere in which the pressure is, e.g., about 1 Pa or less.

The following is an example of a method for producing a nano-porous body used for the insulator 4. A method for producing porous silica will be described as an example of the nano-porous body.

The method for producing porous silica can be divided into two major steps: a step of producing a wet gel, and a step of drying the wet gel (drying process).

First, the step of producing a wet gel will be described. A silica wet gel can be synthesized, e.g., by mixing materials for silica in a solvent and allowing the mixture to undergo a sol-gel reaction. In this case, a catalyst may be used as needed. During the formation of a wet gel, the materials react in the solvent to produce fine particles, the fine particles constitute a three-dimensional network, and thus a reticulate framework is formed. The shape (e.g., the average diameter of voids in the porous silica produced) of the framework can be controlled, e.g., by selecting the materials and the solvent composition or by adding a catalyst or viscosity modifier as needed. In the actual production process, the silica wet gel may be produced in the following manner: the silica materials mixed in the solvent are applied to a substrate and allowed to stand for a given time so that the silica material is gelatinized.

A method for applying the silica material to the substrate is not particularly limited, and any method such as spin coating, dipping, or screen printing may be selected in accordance with the necessary thickness, shape, or the like.

A temperature at which the wet gel is produced is not particularly limited and may be, e.g., in the vicinity of room temperature. If necessary, heating may be performed at a temperature not more than the boiling point of the solvent used.

Examples of the materials for silica include alkoxysilane compounds such as tetramethoxysilane, tetraethoxysilane, trimethoxymethylsilane, and dimethoxydimethylsilane, oligomer of these compounds, water glass compounds such as sodium silicate (silicate of soda) and potassium silicate, and colloidal silica. They may be used individually or as a mixture of two or more compounds.

The solvent is not particularly limited as long as it dissolves the materials to produce silica. For example, general inorganic/organic solvents such as water, methanol, ethanol, propanol, acetone, toluene, and hexane may be used individually or as a mixture of two or more solvents.

Examples of the catalyst include water, acids such as hydrochloric acid, sulfuric acid, and acetic acid, and bases such as ammonia, pyridine, sodium hydroxide, and potassium hydroxide.

The viscosity modifier is not particularly limited as long as it can adjust the viscosity of the solvent mixed with the materials. For example, ethylene glycol, glycerin, polyvinyl alcohol, or silicone oil can be used.

To disperse the electron emission materials in the porous silica, e.g., the electron emission materials as well as the above materials may be mixed and dispersed in the solvent, and then the mixture may be gelatinized.

Next, the step of drying the wet gel will be described. A method for drying the wet gel is not particularly limited. For example, normal drying such as air drying, drying by heating, and drying under reduced pressure, supercritical drying, or freeze drying can be used. In this case, the supercritical drying is preferred to suppress the shrinkage of the gel due to drying. Even if the normal drying is used, the surface of a solid-phase component of the wet gel may be treated so as to have water repellency, thereby suppressing the shrinkage of the gel due to drying.

The solvent that has been used in producing the wet gel can be used as a solvent for the supercritical drying. Alternatively, the solvent included in the wet gel may be substituted beforehand for a solvent that can be handled more easily in the supercritical drying. Any solvent generally used as a supercritical fluid, e.g., alcohols such as methanol, ethanol, and isopropyl alcohol, carbon dioxide, or water can be used for the substitute solvent. Moreover, the solvent included in the wet gel also may be substituted beforehand for acetone, isoamyl acetate, hexane, or the like that are eluted easily with the supercritical fluid.

The supercritical drying may be performed, e.g., in a pressure vessel such as an autoclave. When methanol is used as the supercritical fluid, the wet gel may be dried by maintaining the inside of the autoclave at a pressure of not less than 8.09 MPa and a temperature of not less than 239.4° C., which are the critical conditions of methanol, and by gradually releasing the pressure while the temperature is kept constant. Similarly, when carbon dioxide is used as the supercritical fluid, the wet gel may be dried by maintaining the inside of the autoclave at a pressure of not less than 7.38 MPa and a temperature of not less than 31.1° C. and by gradually releasing the pressure while the temperature is kept constant. Similarly, when water is used as the supercritical fluid, the wet gel may be dried by maintaining the inside of the autoclave at a pressure of not less than 22.04 MPa and a temperature of not less than 374.2° C. and by gradually releasing the pressure while the temperature is kept constant. The drying time may be, e.g., not less than the time it takes for the solvent in the wet gel to be replaced at least one time by the supercritical fluid.

For a method that includes water repellent treatment of the wet gel before drying, a surface treating agent used for the water repellent treatment may react chemically on the surface of a solid-phase component of the wet gel, and then the wet gel may be dried. The water repellent treatment can reduce surface tension generated in the voids of the wet gel, so that the shrinkage of the gel during drying can be suppressed.

Examples of the surface treating agent include a halogen-based silane treating agent such as trimethylchlorosilane or dimethyldichlorosilane, an alkoxy-based silane treating agent such as trimethylmethoxysilane or trimethylethoxysilane, a silicone-based silane treating agent such as hexamethyldisiloxane or dimethylsiloxane oligomer, an amine-based silane treating agent such as hexamethyldisilazane, and alcohol-based treating agent such as propyl alcohol or butyl alcohol. Any other materials also can be used as long as they provide the effect comparable to that of the above surface treating agents.

The use of an inorganic material or organic polymer material also can produce the same nano-porous body. For example, any material generally used in forming ceramics such as aluminium oxide (alumina) can be used. After the nano-porous body is produced by the above method, the electron emission materials may be dispersed and formed inside the nano-porous body using, e.g., a vapor synthetic method.

### EXAMPLES

Hereinafter, the present invention will be described more specifically by way of examples. The present invention is not limited to the following examples.

### Example 1

In Example 1, a thermal switching element 1 as shown in FIG. 19 was produced by using SrTiO₃ for the transition body 3. Al was used for the electrodes 2a, 2b, Al₂O₃ was used for the insulator 9, and Au was used for the electrode 10. FIGS. 20A to 20E show a method for producing the thermal switching element 1 of Example 1.

First, a resist 20 was deposited on SrTiO₃crystals that served as the transition body 3 (FIG. 20A). The resist 20 was made of a positive resist material, and a general resist coating method was used. Then, an Al layer 21 was deposited over the entire surface by sputtering (FIG. 20B). Next, the resist 20 and a portion of the Al layer 21 that was located on the resist 20 were removed by lift-off, and the electrodes 2a, 2b were formed (FIG. 20C). Subsequently, the Al₂O₃ insulator 9 was formed by sputtering (FIG. 20D). Finally, the Au electrode 10 was formed by sputtering (FIG. 20E). Thus, the thermal switching element 1 in FIG. 19 was produced. The distance d (corresponding to the length of one side of the transition body 3) between the electrodes 2a and 2b was about 5 μm, the thickness of the insulator 9 was about 100nm, and the thickness of the electrode 10 was about 2 μm. The size of the transition body 3 as seen from the direction of the arrow E in FIG. 19 was 10 μm×0.5 μm.

Using the thermal switching element 1 thus produced, electric energy was applied to the transition body 3 by applying a voltage between the electrode 10 and the transition body 3, and changes in thermal conductivity between the electrodes 2a and 2b before and after the application of energy were examined. The thermal conductivity between the electrodes 2a and 2b was measured by a Harman method. The Harman method-evaluates the state of heat conduction using a temperature difference between both ends of a sample caused by the application of a current to the sample. Specifically, the thermal conductivity can be determined by a formula STI/ΔT, where S is thermoelectric power (V/K), T is an average temperature (K) of the sample, I is a current value (A), and ΔT (K) is a temperature difference of the sample. Unless otherwise specified, the thermal conductivity was measured at room temperature. The same is true for the following examples.

The evaluation showed that when no voltage was applied between the electrode 10 and the transition body 3, the thermal conductivity between the electrodes 2a and 2b was too small to be measured. Thereafter, a voltage applied between the electrode 10 and the transition body 3 was increased. When the applied voltage was several tens of volts, the thermal conductivity appeared. Thus, it was confirmed that the thermal switching element had the function of controlling heat transfer by the application of a voltage.

Next, a thermal switching element 1 as shown in FIG. 21 was produced, and similarly changes in thermal conductivity between the electrodes 2a and 2b before and after the application of energy were examined. The thermal switching element 1 in FIG. 21 was produced in the following manner. First, SrTiO₃crystals doped with Nb in the range of 0.1 at % to 10 at % (Nb:SrTiO₃) were used as the electrode 2a, on which the SrTiO₃transition body 3 was formed by sputtering. The transition body 3 was formed in a heating atmosphere at about 450° C. to 700° C. The Al electrode 2b, the Al₂O₃ insulator 9, and the Au electrode 10 were formed in the same manner as the thermal switching element 1 in FIG. 19. The thickness (corresponding to the distance between the electrodes 2a and 2b) of the transition body 3 was about 1 μm, and the distance between the electrode 10 and the transition body 3 via the insulator 9 was about 100 nm.

Using the thermal switching element 1 thus produced, electric energy was applied to the transition body 3 by applying a voltage between the electrode 10 and the transition body 3, and changes in thermal conductivity between the electrodes 2a and 2b before and after the application of energy were examined.

Consequently, when no voltage was applied between the electrode 10 and the transition body 3, the thermal conductivity between the electrodes 2a and 2b was too small to be measured. Thereafter, a voltage applied between the electrode 10 and the transition body 3 was increased. When the applied voltage was 2.5 V, the thermal conductivity appeared. Thus, it was confirmed that the thermal switching element had the function of controlling heat transfer by the application of a voltage.

In Example 1, SrTiO₃was used for the transition body. When other materials such as LaTiO₃, (La, Sr) TiO₃, YTiO₃, (Sm, Ca) TiO₃, (Nd, Ca) TiO₃, (Pr, Ca) TiO₃, SrTiO_{3-d} (0<d≦0.1), and (Pr₁₋ₓCaₓ) MnO₃(0<x≦0.5) were used for the transition body 3, the same result was obtained as well. Moreover, oxides expressed by X¹BaX²₂O₆ (where X¹ is at least one element selected from La, Pr, Nd, Sm, Eu, Gd, Tb, Dy, Ho, Er, Tm, and Yb and X² is Mn and/or Co) such as GdBaMn₂O₆ or oxides expressed by (V_{1-y}X³_{y})Oₓ (where 0≦y≦0.5, 1.5≦x≦2.5, and X³ is at least one element selected from Cr, Mn, Fe, Co, and Ni) also provided the same result.

### Example 2

In Example 2, a thermal switching element 1 as shown in FIG. 22 was produced by using SrTiO₃ doped with Cr in the range of 0.1 at % to 10 at % (Cr:SrTiO₃) for the transition body 3.

First, SrTiO₃was used as a substrate 22, on which the SrRuO₃electrode 2a was formed by sputtering. Then, the Cr:SrTiO₃transition body 3 was formed on the electrode 2a, and the Pt electrode 2b was formed on the transition body 3. The transition body 3 and the electrode 2b also were formed by sputtering. The transition body 3 and the electrode 2a were formed in a heating atmosphere at about 450° C. to 700° C. The thicknesses of the electrode 2a, the transition body 3, and the electrode 2b were about 200 nm, about 300 nm, and about 2 μm, respectively.

Using the thermal switching element 1 thus produced, electric energy was applied to the transition body 3 by applying a voltage between the electrodes 2a and 2b, and changes in thermal conductivity between the electrodes 2a and 2b before and after the application of energy were examined. The thermal conductivity was measured in the same manner as Example 1.

Consequently, when no voltage was applied between the electrodes 2a and 2b, the thermal conductivity between the electrodes 2a and 2b. was too small to be measured. Thereafter, a voltage applied between the electrodes 2a and 2b was increased. When the applied voltage was about 0.5 V, the thermal conductivity appeared. Thus, it was confirmed that the thermal switching element had the function of controlling heat transfer by the application of a voltage. Moreover, the thermal conductivity of the thermal switching element 1 exhibited hysteresis. Therefore, even if a voltage applied between the electrodes 2a and 2b was reduced to zero after the thermal conductivity appeared, the thermal conductivity between the electrodes 2a and 2b was maintained without any change. Subsequently, the thermal conductivity between the electrodes 2a and 2b disappeared by applying a voltage opposite to the direction of the first applied voltage between the electrodes. This showed that a nonvolatile thermal switching element was achieved by selecting the material for the transition body 3. A thermal device with more reduced power consumption can be constructed by using the nonvolatile thermal switching element.

In Example 2, Cr:SrTiO₃ was used for the transition body. When other materials such as SrZrO₃, (La, Sr)TiO₃, Y(Ti, V)O₃, SrTiO_{3-d} (0<d≦0.1), and (Pr₁₋ₓCaₓ) MnO₃ (0<x≦0.5) were used for the transition body 3, the same result was obtained as well. Moreover, oxides expressed by X¹BaX²₂O₆ (where X¹ is at least one element selected from La, Pr, Nd, Sm, Eu, Gd, Th, Dy, Ho, Er, Tm, and Yb and X² is Mn and/or Co) such as NdBaMn₂O₆ or oxides expressed by (V_{1-y}X³_{y}) O_{X} (where 0≦y≦0.5, 1.5≦x≦2.5, and X³ is at least one element selected from Cr, Mn, Fe, Co, and Ni) also provided the same result.

### Example 3

In Example 3, a thermal switching element 1 as shown in FIG. 23 was produced by using a laminate of SrTiO₃ and LaSrMnO₃ for the transition body 3.

The Nb:SrTiO₃ was used as a substrate 22, on which the following thin films were deposited by laser ablation. The deposition was performed in an oxygen atmosphere in the range of 10 mmTorr to 500 mmTorr while heating at 450° C. to 700° C. First, SrTiO₃ (thickness: 50 nm) was arranged on the substrate 22, and LaSrMnO₃ (thickness: 100 nm) was arranged on the SrTiO₃, thereby forming the transition body 3. Then, SrRuO₃ (thickness: 10 nm) was arranged on the transition body 3. Next, Pt (thickness: 240 nm) was arranged on the SrRuO₃ by sputtering. The sputtering was performed at 400° C. Subsequently, the laminate of SrRuO₃ and Pt was microfabricated into the electrodes 2a and 2b, as shown in FIG. 23. Then, Al₂O₃ was arranged as the insulator 9 so that the thickness measured from the surfaces of the electrodes 2a, 2b was 80 nm. Finally, Au (thickness: 900 nm) was provided as the electrode 10. The electrode 10 was divided into a plurality of electrodes (a total of 15 electrodes, part of which is shown in FIG. 23) to improve the efficiency of a magnetic field applied to the transition body 3.

Using the thermal switching element 1 thus produced, a magnetic field 12 was applied to the transition body 3 by allowing a current 11 to flow through the electrode 10, and changes in thermal conductivity between the electrodes 2a and 2b before and after the application of magnetic energy were examined. The thermal conductivity was measured in the same manner as Example 1. The current flowed through all the plurality of electrodes 10 in the same direction.

Consequently, when no current flowed through the electrode 10, the thermal conductivity between the electrodes 2a and 2b was too small to be measured. Thereafter, a current flowing through the electrode 10 was increased. When the current was about 2.5 mA per electrode 10, the thermal conductivity appeared. Thus, it was confirmed that the thermal switching element had the function of controlling heat transfer by the application of a magnetic field.

In Example 3, (La, Sr)MnO₃ was used for the transition body. When other materials such as (La, Sr)₃Mn₂O₇, X⁴₂FeReO₆, X⁴₂FeMoO₆, (La, X⁴)₂CuO₄, (Nd, Ce)₂CuO₄, (La, X⁴)₂NiO₄, LaMnO₃, YMnO₃, (Sm, Ca) MnO₃, (Nd, Ca)MnO₃, (Pr, Ca)MnO₃, (La, X⁴)FeO₃, YFeO₃, (Sm, X⁴)FeO₃, (Nd, X⁴) FeO₃, (Pr, X⁴)FeO₃, (La, X⁴)CoO₃, (Y, X⁴) VO₃, (Bi, X⁴)MnO₃, and SrTiO_{3-d} (0<d≦0.1) were used for the transition body 3, the same result was obtained as well. In this case, X⁴ is at least one element selected from Sr, Ca, and Ba. Moreover, oxides expressed by X¹BaX²₂O₆ (where X¹ is at least one element selected from La, Pr, Nd, Sm, Eu, Gd, Tb, Dy, Ho, Er, Tm, and Yb and X² is Mn and/or Co) such as SmBaMn₂O₆ or oxides expressed by (V_{1-y}X³_{y})Oₓ (where 0≦y≦0.5, 1.5≦x≦2.5, and X³ is at least one element selected from Cr, Mn, Fe, Co, and Ni) also provided the same result.

### Example 4

In Example 4, a thermal switching element including the configuration as shown in FIG. 14B was produced.

MgO was used as a substrate, on which the following thin films were layered by laser ablation. The layering was performed in an oxygen atmosphere in the range of 10 mmTorr to 500 mmTorr while heating at 450° C. to 700° C. First, ITO (Sn-doped In₂O₃ having a thickness of 50 nm) was layered on the substrate, and (Pr, Ca) MnO₃ (thickness: 100 nm) was layered on the ITO, thereby forming the transition body 3. Next, Pt (thickness: 240 nm) was layered on SrRuO₃ by sputtering. The sputtering was performed at 400° C. Subsequently, the laminate of SrRuO₃ and Pt was microfabricated into the electrodes 2a and 2b. Thus, the thermal switching element was produced.

Using the thermal switching element thus produced, light energy was applied to the transition body 3 by allowing pulsed laser light (wavelength: 532 nm) to enter from the substrate side, and changes in thermal conductivity between the electrodes 2a and 2b before and after the application of light energy were examined. The thermal conductivity was measured in the same manner as Example 1.

Consequently, when no light entered the transition body 3, the thermal conductivity between the electrodes 2a and 2b was too small to be measured. Thereafter, pulsed laser light entered the transition body 3. When the transition body 3 was irradiated with an ultrashort pulse of 100 femtoseconds at about 0.5 W, the thermal conductivity appeared. Thus, it was confirmed that the thermal switching element had the function of controlling heat transfer by the irradiation of light. Even if the wavelength of the pulsed laser light was varied from the near-infrared region to the visible light region, the same result also was obtained.

### Example 5

In Example 5, a thermal switching element including the configuration as shown in FIG. 15 was produced.

LiTaO₃ was used as a substrate, on which the following thin films were formed by magnetron sputtering. The film formation was performed in an oxygen-argon mixed atmosphere (a partial pressure ratio Ar:O₂=1:1) in the range of 10 mmTorr to 500 mmTorr while heating at 450° C. to 700° C. First, V₂O₃ (thickness: 50 nm) was formed on the substrate as the transition body 3. Next, Pt (thickness: 50 nm) was formed on the transition body 3 at 400° C., and then was microfabricated into the electrodes 2a and 2b. Subsequently, Ni—Cr alloy (thickness: 100 nm) was formed by electron-beam evaporation as the resistor 15. Further, Au (thickness: 300 nm) was formed as the electrode 10.

Using the thermal switching element thus produced, the resistor 15 generated heat by allowing a current to flow through the electrode 10, and the generated heat was applied to the transition body 3. Then, changes in thermal conductivity between the electrodes 2a and 2b before and after the application of thermal energy were examined. The thermal conductivity was measured in the same manner as Example 1.

Consequently, when no current flowed through the electrode 10, i.e., the resistor 15 did not generate heat, the thermal conductivity between the electrodes 2a and 2b was too small to be measured. Thereafter, a current flowing through the electrode 10 was increased. When the current was about 4 mA, the thermal conductivity appeared. Thus, it was confirmed that the thermal switching element had the function of controlling heat transfer by the application of heat.

In Example 5, V₂O₃ was used for the transition body. When other materials such as VOₓ(1.5≦x≦2.5), Ni(S, Se)₂, EuNiO₃, SmNiO₃, (Y, X⁴)VO₃, SrTiO_{3-d}(0<d≦0.1), and (Pr₁₋ₓCaₓ) MnO₃ (0<x≦0.5) were used for the transition body 3, the same result was obtained as well. In this case, X⁴ is at least one element selected from Sr, Ca, and Ba. Moreover, oxides expressed by X¹BaX²₂O₆ (where X¹ is at least one element selected from La, Pr, Nd, Sm, Eu, Gd, Tb, Dy, Ho, Er, Tm, and Yb and X² is Mn and/or Co) or oxides expressed by (V_{1-y}X³_{y}) Oₓ (where 0≦y≦0.5, 1.5≦x≦2.5, and X³ is at least one element selected from Cr, Mn, Fe, Co, and Ni) also provided the same result.

### Example 6

In Example 6, a thermal switching element 1 as shown in FIG. 24 was produced.

LiTaO₃ (thickness: 0.8μm), which is a kind of piezoelectric material, was used as the deformable body 16, on which the following thin films were provided by sputtering. The arrangement of each layer was performed in an argon-nitrogen mixed atmosphere (a partial pressure ratio Ar:N₂=3: 2) in the range of 0.1 mmTorr to 100 mmTorr while heating at 200° C. to 500° C. First, LaVO₃ (thickness: 100 nm) was arranged on the deformable body 16 as the transition body 3. Next, Al (thickness: 1000 nm) was arranged on the transition body 3 so as to form the electrodes 2a and 2b. Further, Al (thickness: 1000nm) was arranged on the surface of the deformable body 16 that was opposite to the surface in contact with the transition body 3 so as to form the electrode 10. The electrode 10 was in the form of a comb by using a photolithographic technique, as shown in FIG. 24. The space between the comb electrodes 10 was 2 μm.

Using the thermal switching element 1 thus produced, the deformable body 16 was deformed by the application of a voltage with the electrode 10, and pressure resulting from the deformation was applied to the transition body 3. Then, changes in thermal conductivity between the electrodes 2a and 2b before and after the application of mechanical energy were examined. The thermal conductivity was measured in the same manner as Example 1.

Consequently, when no voltage was applied to the deformable body 16, the thermal conductivity between the electrodes 2a and 2b was too small to be measured. Thereafter, a voltage applied to the deformable body 16 was increased. When the applied voltage was about 0.5 V, the thermal conductivity appeared. Thus, it was confirmed that the thermal switching element had the function of controlling heat transfer by the application of pressure, which is a kind of mechanical energy.

In Example 6, LaVO₃ was used for the transition body. When other materials such as (Y, X⁴)MnO₃, (La, X⁴)MnO₃, (Bi, X⁴)MnO₃, (Bi, X⁴)TiO₃, (Bi, X⁴)₃Ti₂O₇, (Pb, X⁴)TiO₃, SrTiO_{3-d}(0<d<0.1), and (Pr₁₋ₓCaₓ)MnO₃ (0<x<0.5) were used for the transition body 3, the same result was obtained as well. In this case, X⁴ is at least one element selected from Sr, Ca, and Ba. Moreover, oxides expressed by X¹BaX²₂O₆ (where X¹is at least one element selected from La, Pr, Nd, Sm, Eu, Gd, Th, Dy, Ho, Er, Tm, and Yb and X² is Mn and/or Co) such as SmBaMn₂O₆ or oxides expressed by (V_{1-y}X³_{y})Oₓ (where 0≦y≦0.5, 1.5≦x≦2.5, and X³ is at least one element selected from Cr, Mn, Fe, Co, and Ni) also provided the same result. In Example 6, LiTaO₃ was used as the deformable body 16. When other materials such as LiNbO₃, (Ba, Sr)TiO₃, and Pb(Zr, Ti)O₃ were used as the deformable body 16, the same result was obtained as well.

### Example 7

In Example 7, a thermal switching element 1 including the insulator 4 as shown in FIG. 2 was produced.

First, SrRuO₃ (thickness: 200 nm) was provided on a SrTiO₃ substrate as the electrode 2a. Then, SrTiO₃ doped with Cr in the range of 0.1 at % to 10 at % (Cr:SrTiO₃ having a thickness of 300 nm) was provided on the electrode 2a as the transition body 3. The electrode 2a and the transition body 3 were formed by laser ablation (at a substrate temperature of 450° C. to 700° C.).

Next, a porous silica layer (thickness: about 0.1 μm) was formed by the above sol-gel process and provided on the transition body 3 so as to form the insulator 4. The following is an explanation of a specific method for producing the porous silica layer.

A solution including a silica material was prepared by mixing tetramethoxysilane, ethanol, and ammonia aqueous solution (0.1N) at a molar ratio of 1:3:4. Diamond particles having an average particle diameter of about 10 nm were dispersed in the solution as electron emission materials. After stirring the solution, it had a viscosity suitable for application. Then, the solution was applied to the transition body 3 in a thickness of about 0.1 μm by spin coating. Subsequently, the applied silica sol was polymerized and gelatinized by drying. The silica gel thus formed was evaluated using a high-resolution scanning electron microscope. The evaluation showed that a wet gel structure including a three-dimensional network of Si—O—Si bond was formed as shown in FIG. 3. Moreover, the evaluation also showed that the diamond particles (the electron emission materials) were dispersed uniformly.

Next, the wet gel thus produced was washed with ethanol and substituted with a solvent, which then was subjected to supercritical drying with carbon dioxide, thereby producing a porous silica layer. The supercritical drying was performed in such a manner that a pressure of 12 MPa and a temperature of 50° C. were maintained for four hours, then the pressure was released gradually to atmospheric pressure, and subsequently the temperature was reduced to room temperature. The dried sample was annealed at 400° C. in a nitrogen atmosphere, and thus adsorbates on the porous silica layer were removed.

The porosity of the porous silica layer evaluated using a Brunauer-Emmett-Teller (BET) method was about 92%. The average pore diameter of the porous silica layer also was estimated by the same technique, and the resultant value was about 20 nm.

A laminate including the electrode 2a, the transition body 3, and the insulator 4 thus produced was annealed at 400° C. in a hydrogen atmosphere. This annealing allows the surface of the diamond particles included in the porous silica layer to be hydrogenated, so that the diamond particles can be more activated as electron emission materials.

Finally, Pt (thickness: 2000 nm) was provided on the insulator 4 as the electrode 2b by sputtering.

Using the thermal switching element 1 thus produced, electric energy was applied to the transition body 3 by applying a voltage between the electrodes 2a and 2b, and changes in thermal conductivity between the electrodes 2a and 2b before and after the application of energy were examined. The thermal conductivity was measured in the same manner as example 1.

Consequently, when no voltage was applied between the electrodes 2a and 2b, the thermal conductivity between the electrodes 2a and 2b was too small to be measured. Thereafter, a voltage applied between the electrodes 2a and 2b was increased. When the applied voltage was about 5 V, the thermal conductivity appeared. Thus, it was confirmed that the thermal switching element had the function of controlling heat transfer by the application of a voltage.

The radiant current density between the two electrodes was measured at the time of appearance of the thermal conductivity, and the resultant value was several 10 mA/cm². Moreover, the electrode 2a came into contact with Au that was kept at 30° C. while maintaining the thermal conductivity of the thermal switching element 1, and a change in temperature of the electrode 2a was measured. Consequently, a phenomenon was observed in which the temperature of the electrode 2a was reduced by about 30 degrees, i.e., was reduced to about 0° C. Thus, it was confirmed that the thermal switching element including the insulator 4 also functioned as a cooling element.

In Example 7, a thermal switching element 1 including the insulator 4 and the electrode 8 as shown in FIG. 4 was produced, and the same evaluation was performed.

First, SrRuO₃ (thickness: 200 nm) was provided on a SrTiO₃ substrate as the electrode 2a. Then, SrTiO₃ doped with Cr in the range of 0.1 at % to 10 at % (Cr:SrTiO₃ having a thickness of 300 nm) was provided on the electrode 2a as the transition body 3. Next, (Sr, Ca, Ba)C0₃ (thickness: 50 nm) was arranged on the transition body 3 as the electrode 8, and a porous silica layer (thickness: 0.1 μm) was arranged on the electrode 8 in the same manner as described above so as to form the insulator 4. The electrode 2a, the transition body 3, and the electrode 8 were formed by laser ablation (at a substrate temperature of 450° C. to 700° C.). Finally, Pt (thickness: 2000 nm) was arranged on the insulator 4 as the electrode 2b by sputtering. Thus, the thermal switching element 1 as shown in FIG. 4 was produced.

Using the thermal switching element 1 thus produced, electric energy was applied to the transition body 3 by applying a voltage between the electrodes 2a and 2b, and changes in thermal conductivity between the electrodes 2a and 2b before and after the application of energy were examined. The thermal conductivity was measured in the same manner as Example 1.

Consequently, when no voltage was applied between the electrodes 2a and 2b, the thermal conductivity between the electrodes 2a and 2b was too small to be measured. Thereafter, a voltage applied between the electrodes 2a and 2b was increased. When the applied voltage was about 1.8 V, the thermal conductivity appeared. Thus, it was confirmed that the thermal switching element had the function of controlling heat transfer by the application of a voltage. Considering the fact that the voltage required for the thermal switching element that did not include the electrode 8 was about 5 V, the efficiency was improved two or more times by the use of the electrode 8.

The electrode 2a came into contact with Au that was kept at 30° C. while maintaining the thermal conductivity of the thermal switching element 1, and a change in temperature of the electrode 2a was measured. Consequently, a phenomenon was observed in which the temperature of the electrode 2a was reduced. Thus, it was confirmed that the thermal switching element including the insulator 4 also functioned as a cooling element.

In Example 7, the porous silica layer having a thickness of about 0.1 μm was used as the insulator 4. Even if the thickness of the insulator 4 ranged from about 0.05 μm to 10 μm, the same result was obtained as well. Since the optimum thickness of the insulator 4 may vary with the structure or material of the element, the thickness of the insulator 4 is not limited to the above range.

In Example 7, (Sr, Ca, Ba) C0₃ was used as the electrode 8. When other materials such as (Sr, Ca, Ba)—O, Cs—O, Cs—Sb, Cs—Te, Cs—F, Rb—O, Rb—Cs—O, and Ag—Cs—O were used as the electrode 8, the same result was obtained as well.

### Example 8

In Example 8, a thermal switching element 1 as shown in FIG. 22 was produced by using Ca₃Co₄O₉ for the transition body 3.

First, sapphire (Al₂O₃) was used as a substrate 22, on which the NaCo₂O₆ electrode 2a was formed by sputtering. Then, the Ca₃Co₄O₉ transition body 3 was formed on the electrode 2a, and the NaCo₂O₆ electrode 2b was formed on the transition body 3. The transition body 3 and the electrode 2b also were formed by sputtering. The transition body 3 and the electrode 2a were formed in a heating atmosphere at about 450° C. to 850° C. The thicknesses of the electrode 2a, the transition body 3, and the electrode 2b were about 200 nm, about 300 nm, and about 2 μm, respectively.

Using the thermal switching element 1 thus produced, electric energy was applied to the transition body 3 by applying a voltage between the electrodes 2a and 2b, and changes in thermal conductivity between the electrodes 2a and 2b before and after the application of energy were examined. The thermal conductivity was measured in the same manner as Example 1.

Consequently, when no voltage was applied between the electrodes 2a and 2b, the thermal conductivity between the electrodes 2a and 2b was too small to be measured. Thereafter, a voltage applied between the electrodes 2a and 2b was increased. When the applied voltage was about 0.5 V, the thermal conductivity appeared. Thus, it was confirmed that the thermal switching element had the function of controlling heat transfer by the application of a voltage. Moreover, the thermal conductivity of the thermal switching element 1 exhibited hysteresis. Therefore, even if a voltage applied between the electrodes 2a and 2b was reduced to zero after the thermal conductivity appeared, the thermal conductivity between the electrodes 2a and 2b was maintained without any change. Subsequently, the thermal conductivity between the electrodes 2a and 2b disappeared by applying a voltage opposite to the direction of the first applied voltage between the electrodes. This showed that a nonvolatile thermal switching element was achieved by selecting the material for the transition body 3. A thermal device with more reduced power consumption can be constructed by using the nonvolatile thermal switching element.

In Example 8, Ca₃Co₄O₉ was used for the transition body 3. When delafossite expressed by CuX₅O₂ (where X⁵ is at least one element selected from Al, In, Ga, and Fe) or the like was used for the transition body 3, the same result was obtained as well.

As described above, the present invention can provide a thermal switching element that has a quite different configuration from that of a conventional technique and can control heat transfer by the application of energy, and a method for manufacturing the thermal switching element.

There is no particular limitation to the application of the thermal switching element of the present invention as long as it is used in a portion that performs heat transfer, e.g., a heat dissipating portion of a semiconductor chip such as a CPU used in information terminals, a heat transfer portion of a freezer, refrigerator, or air conditioner, which are typical products as a heat engine, or a heat flow control portion of heat wiring. In this case, the thermal switching element of the present invention can be used not only.in a portion that requires control of heat transfer, but also in a portion that merely transfers heat without controlling the heat transfer.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A thermal switching element comprising:
a first electrode;
a second electrode; and
a transition body arranged between the first electrode and the second electrode,
wherein the transition body comprises a material that causes an electronic phase transition by application of energy,
the material that causes an electronic phase transition consists essentially of an oxide with a composition expressed by SrTiO₃,and
thermal conductivity between the first electrode and the second electrode is changed by the application of energy to the transition body, so that heat is more difficult to be transferred from the first electrode to the second electrode through the transition body of an OFF state compared with the transition body on an ON state, when a temperature of the first electrode is higher than a temperature of the second electrode.

2. The thermal switching element according to claim 1, wherein the application of energy allows heat to be transferred between the first electrode and the second electrode more easily than before the application of energy.

3. The thermal switching element according to claim 1, wherein electronic thermal conductivity of the transition body is changed by the application of energy.

4. The thermal switching element according to claim 1, wherein the transition body causes an insulator-metal transition by the application of energy.

5. The thermal switching element according to claim 1, wherein the application of energy allows thermions to move in the transition body more easily than before the application of energy.

6. The thermal switching element according to claim 1, wherein the applied energy is at least one selected from the group consisting of electric energy, light energy, mechanical energy, magnetic energy, and thermal energy.

7. The thermal switching element according to claim 6, wherein the application of energy is performed by injecting electrons or holes into the transition body or by inducing electrons or holes in the transition body.

8. The thermal switching element according to claim 6, wherein the application of energy is performed by applying a voltage between the first electrode and the second electrode.

9-16. (canceled)

17. The thermal switching element according to claim 1, wherein the material that causes an electronic phase transition comprises at least one selected from the group consisting of a Mott insulator and a magnetic semiconductor.

18. The thermal switching element according to claim 1, further comprising a first insulator,
wherein the first insulator is provided between the transition body and the second electrode.

19. The thermal switching element according to claim 18, further comprising a third electrode,
wherein the third electrode is provided between the transition body and the first insulator.

20. The thermal switching element according to claim 1, further comprising a fourth electrode for applying the energy to the transition body.

21. The thermal switching element according to claim 20, further comprising a second insulator,
wherein the second insulator is arranged between the transition body and the fourth electrode.

22. The thermal switching element according to claim 20, wherein the application of energy is performed by applying a voltage between the fourth electrode and the transition body.

23. The thermal switching element according to claim 20, wherein the application of energy is performed by allowing a current to flow through the fourth electrode.

24. The thermal switching element according to claim 23, wherein the application of energy is performed by allowing a current to flow through the fourth electrode so as to generate a magnetic field and introducing the magnetic field into the transition body.

25. The thermal switching element according to claim 18, wherein the first insulator is a vacuum.

26. The thermal switching element according to claim 18, wherein the first insulator is a tunnel insulator.

27. The thermal switching element according to claim 18, wherein the first insulator is made of an insulating material that has a porous structure.

28. The thermal switching element according to claim 27, wherein the insulating material comprises an electron emission material.

29. The thermal switching element according to claim 1, functioning as a cooling element that conducts heat from one electrode selected from the first electrode and the second electrode to the other electrode.

30-36. (canceled)

37. The thermal switching element according to claim 1, wherein the oxide includes Cr.

38. The thermal switching element according to claim 1, wherein the oxide consists of SrTiO₃.

39. The thermal switching element according to claim 1, wherein the oxide consists of SrTiO₃:Cr.
